(19) United States
(12) Patent Application Publication
(10) Pub. No.: US 2026/0129994 A1
(43) Pub. Date: May 7, 2026

(54) IMAGE SENSOR INCLUDING NANO-PHOTONIC MICROLENS ARRAY AND ELECTRONIC APPARATUS INCLUDING THE SAME

(71) Applicant: SAMSUNG ELECTRONICS CO., LTD., Suwon-si (KR)

(72) Inventors: Sangeun MUN, Suwon-si (KR); Sookyoung ROH, Suwon-si (KR); Yohwan NOH, Suwon-si (KR); Jaeho LEE, Suwon-si (KR)

(73) Assignee: SAMSUNG ELECTRONICS CO., LTD., Suwon-si (KR)

(21) Appl. No.: 19/377,728

(22) Filed: Nov. 3, 2025

(30) Foreign Application Priority Data
Nov. 5, 2024 (KR) 10-2024-0155685

(51) Int. Cl. H10F 39/00

(52) U.S. Cl. CPC H10F 39/8063; H10F 39/8023

(57) ABSTRACT

An image sensor may include a sensor substrate including a plurality of pixels configured to sense incident light, and a nano-photonic microlens array including a plurality of nano-photonic microlenses respectively corresponding to the plurality of pixels. Each of the plurality of nano-photonic microlenses may include a plurality of nanostructures periodically arranged in two dimensions along a first direction and a second direction to condense incident light on corresponding pixels. An interval between two adjacent nanostructures may be greater than an arrangement period of the plurality of nanostructures in each of the plurality of nano-photonic microlenses.

### CROSS-REFERENCE TO RELATED APPLICATION

This application is based on and claims priority under 35 U.S.C. §119 to Korean Patent Application No. 10-2024-0155685, filed on November 05, 2024, in the Korean Intellectual Property Office, the disclosure of which is incorporated by reference herein in its entirety.

### BACKGROUND

### Field

The disclosure relates to an image sensor having a nano-photonic microlens array and an electronic apparatus including the same.

### Description of Related Art

The number of pixels included in image sensors has been gradually increased, and accordingly, pixel miniaturization may be required. Securing the quantity of light and removing noise are important issues for pixel miniaturization.

Image sensors generally display images of various colors or sense a color of incident light by using a color filter. However, because the color filter absorbs light of remaining colors except for light of a corresponding color, light utilization efficiency of the color filter may be reduced. For example, in the case of a red-green-blue (RGB) color filter, only one-third of incident light is transmitted and remaining two-thirds are absorbed, and thus, light utilization efficiency of the RGB color filter is only about 33%, which means that light loss is very high.

Accordingly, various methods for improving the performance of an image sensor by using nanostructures are being explored.

### SUMMARY

Provided are an image sensor in which an effective diameter of a nano-photonic microlens formed by a nanostructure is different for each color of light sensed by each pixel, and an electronic apparatus including the same.

According to an aspect of the disclosure, an image sensor may include: a sensor substrate including a plurality of pixels configured to sense incident light; and a nano-photonic microlens array including a plurality of pixel corresponding regions, the plurality of pixel corresponding regions respectively corresponding to the plurality of pixels, wherein at least two of the plurality of pixel corresponding regions correspond to respective pixels from among the plurality of pixels that are configured to sense light of different wavelengths from each other, wherein each pixel corresponding region from among the plurality of pixel corresponding regions includes a nano-photonic microlens, from among nano-photonic microlenses, including at least one nanostructure from among a plurality of nanostructures of the nano-photonic microlens array, the nano-photonic microlenses configured to condense the incident light in a respective one of the plurality of pixel corresponding regions, and wherein effective diameters of the nano-photonic microlenses of the at least two of the plurality of pixel corresponding regions are different from each other.

According to an aspect of the disclosure, an electronic apparatus may include: a lens assembly configured to form an optical image of a subject; an image sensor configured to convert the optical image formed by the lens assembly into an electrical signal; and a processor configured to process a signal generated by the image sensor, wherein the image sensor includes: a sensor substrate including a plurality of pixels configured to sense incident light; and a nano-photonic microlens array including a plurality of pixel corresponding regions, the plurality of pixel corresponding regions respectively corresponding to the plurality of pixels, wherein at least two of the plurality of pixel corresponding regions correspond to respective pixels from among the plurality of pixels that are configured to sense light of different wavelengths from each other, wherein each pixel corresponding region from among the plurality of pixel corresponding regions includes a nano-photonic microlens, from among nano-photonic microlenses, including at least one nanostructure from among a plurality of nanostructures of the nano-photonic microlens array, the nano-photonic microlenses configured to condense the incident light in a respective one the plurality of pixel corresponding regions, and wherein effective diameters of the nano-photonic microlenses of the at least two of the plurality of pixel corresponding regions are different from each other.

Additional aspects of the disclosure will be set forth in part in the description which follows and, in part, will be apparent from the description, or may be learned by practice of example embodiments of the disclosure.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a block diagram of an image sensor according to an embodiment;

FIG. 2 is a plan view illustrating an arrangement of a pixel array of an image sensor according to an embodiment;

FIG. 3 is a plan view schematically showing an arrangement of a sensor substrate provided in a pixel array of an image sensor according to an embodiment;

FIG. 4 is a plan view schematically showing an arrangement of a color filter array provided in a pixel array of an image sensor according to an embodiment;

FIG. 5 is a plan view schematically showing an arrangement of a nano-photonic microlens array provided in a pixel array of an image sensor according to an embodiment;

FIG. 6 is a cross-sectional view taken along a line A-A’ of FIG. 2 according to an embodiment;

FIG. 7 is a cross-sectional view taken along a line B-B’ of FIG. 2 according to an embodiment;

FIG. 8 is a plan view illustrating an arrangement of nanostructures included in a nano-photonic microlens array according to an embodiment;

FIG. 9 is a plan view illustrating an arrangement of nanostructures included in a nano-photonic microlens array according to an embodiment;

FIG. 10 is a plan view illustrating an arrangement of nanostructures included in a nano-photonic microlens array according to an embodiment;

FIG. 11 is a plan view illustrating an arrangement of nanostructures included in a nano-photonic microlens array according to an embodiment;

FIG. 12 is a plan view illustrating an arrangement of nanostructures included in a nano-photonic microlens array according to an embodiment;

FIG. 13 is a plan view illustrating an arrangement of nanostructures included in a nano-photonic microlens array according to an embodiment;

FIG. 14 is a plan view illustrating an arrangement of nanostructures included in a nano-photonic microlens array according to an embodiment;

FIG. 15 is a plan view illustrating an arrangement of nanostructures included in a nano-photonic microlens array according to an embodiment;

FIG. 16 is a plan view illustrating a pixel array according to a chief ray angle according to an embodiment;

FIG. 17 is a plan view illustrating an arrangement of nanostructures included in a peripheral portion of a nano-photonic microlens array according to an embodiment;

FIG. 18 is a plan view illustrating an arrangement of nanostructures included in a peripheral portion of a nano-photonic microlens array according to an embodiment;

FIG. 19 is a cross-sectional view taken along a line A-A’ of FIG. 2 according to an embodiment;

FIG. 20 is a plan view illustrating an arrangement of a pixel array according to an embodiment;

FIG. 21 is a plan view illustrating an arrangement of nanostructures included in a nano-photonic microlens array of the pixel array of FIG. 20;

FIG. 22 is a block diagram schematically illustrating an electronic apparatus including an image sensor according to embodiments;

FIG. 23 is a block diagram schematically illustrating a camera module of FIG. 22;

FIG. 24 is a block diagram of an electronic apparatus including a multi-camera module; and

FIG. 25 is a detailed block diagram of a camera module of the electronic apparatus illustrated in FIG. 24.

### DETAILED DESCRIPTION

Reference will now be made in detail to non-limiting example embodiments of the disclosure with reference to the accompanying drawings, wherein like reference numerals refer to like elements throughout. In this regard, the embodiments of the disclosure may have different forms and should not be construed as being limited to the descriptions set forth herein. Accordingly, example embodiments are merely described below, by referring to the figures, to explain example aspects of the disclosure. As used herein, the term “and/or” includes any and all combinations of one or more of the associated listed items. Expressions such as “at least one of,” when preceding a list of elements, modify the entire list of elements and do not modify the individual elements of the list.

Hereinafter, an image sensor including a nano-photonic microlens array and an electronic apparatus including the same will be described in detail with reference to the accompanying drawings. Embodiments described below are merely illustrative, and various modifications are possible from these embodiments. In the following drawings, the same reference numerals refer to the same components, and the size of each component in the drawings may be exaggerated for clarity and convenience of description.

Hereinafter, the term “upper portion” or “on” may also include “to be present on the top, bottom, left or right portion on an indirect contact basis” as well as “to be present just on the top, bottom, left or right portion on a direct contact basis.”

The terms “first,” “second,” etc. may be used to describe various components, but are used only for the purpose of distinguishing one component from another component. These terms do not limit the difference in material or structure of components.

Singular expressions include plural expressions unless they are explicitly meant differently in context. In addition, when a part “includes” or “comprises” a component, this means that it may include more other components, rather than excluding other components, unless otherwise stated.

Further, the terms “unit,” “module,” or the like mean a unit that processes at least one function or operation, which may be implemented in hardware or software or implemented in a combination of hardware and software.

The use of the term “the” and similar indicative terms may correspond to both singular and plural.

Steps constituting a method may be performed in any appropriate order unless there is a clear statement that the steps should be performed in the order described. In addition, the use of all illustrative terms (e.g., etc.) is simply intended to detail example aspects of the disclosure, and the scope of the disclosure is not limited due to the terms.

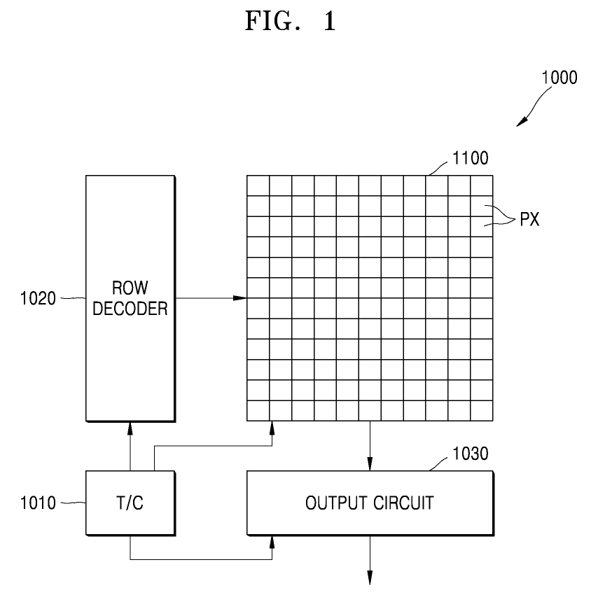

FIG. 1 is a block diagram of an image sensor according to an embodiment. Referring to FIG. 1, an image sensor 1000 may include a pixel array 1100, a timing controller (T/C) 1010, a row decoder 1020, and an output circuit 1030. The image sensor 1000 may include a charge coupled device (CCD) image sensor or a complementary metal oxide semiconductor (CMOS) image sensor.

The pixel array 1100 may include pixels arranged two-dimensionally in a plurality of rows and columns. The row decoder 1020 may select one of the rows of the pixel array 1100 in response to a row address signal output from the timing controller 1010. The output circuit 1030 may output a light sensing signal in units of columns from a plurality of pixels arranged along the selected row. To this end, the output circuit 1030 may include a column decoder and an analog-to-digital converter (ADC). For example, the output circuit 1030 may include a plurality of analog-to-digital converters (ADCs) arranged for each column between a column decoder and the pixel array 1100, or one ADC arranged at the output end of the column decoder. The timing controller 1010, the row decoder 1020, and the output circuit 1030 may be implemented together as one chip or as separate chips. A processor for processing an image signal output through the output circuit 1030 may be implemented as one chip together with the timing controller 1010, the row decoder 1020, and the output circuit 1030.

The pixel array 1100 may include a plurality of pixels PX that sense light of different wavelengths. The arrangement of pixels may be implemented in various ways.

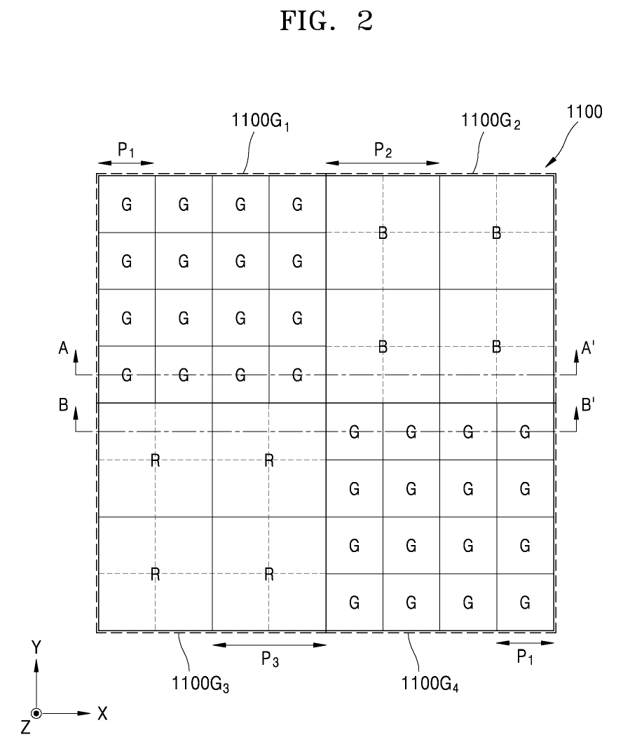

FIG. 2 illustrates an arrangement of a pixel array of an image sensor according to an embodiment.

Referring to FIG. 2, a pixel array 1100 of the image sensor 1000 may include a unit pattern. One unit pattern may include a plurality of unit pixels (e.g., a first unit pixel 1100G₁, a second unit pixel 1100G₂, a third unit pixel 1100G₃, and a fourth unit pixel 1100G₄). For example, a first unit pixel 1100G₁ may be provided in the first row and the first column of the unit pattern, a second unit pixel 1100G₂ may be provided in the first row and the second column of the unit pattern, a third unit pixel 1100G₃ may be provided in the second row and the first column of the unit pattern, and a fourth unit pixel 1100G₄ may be provided in the second row and the second column of the unit pattern. These unit patterns may be two-dimensionally repeatedly arranged in a first direction (e.g., X direction) and a second direction (e.g., Y direction).

Each of the plurality of unit pixels (e.g., the first unit pixel 1100G₁, the second unit pixel 1100G₂, the third unit pixel 1100G₃, and the fourth unit pixel 1100G₄) may include a plurality of pixels provided in a 4×4 arrangement or 2×2 arrangement. For example, each of the first unit pixel 1100G₁ and the fourth unit pixel 1100G₄ may include a plurality of green pixels G arranged in a 4×4 arrangement, the second unit pixel 1100G₂ may include a plurality of blue pixels B arranged in a 2×2 arrangement, and the third unit pixel 1100G₃ may include a plurality of red pixels R arranged in a 2×2 arrangement.

A width P₂ of each of the plurality of blue pixels B arranged in a 2×2 arrangement in the second unit pixel 1100G₂ and/or a width P₃ of each the plurality of red pixels R arranged in a 2×2 arrangement in the third unit pixel 1100G₃ may be greater than a width P₁ of each of the green pixels G arranged in a 4×4 arrangement in the first unit pixel 1100G₁ and the fourth unit pixel 1100G₄. For example, the width P₂ of the blue pixel B or the width P₃ of the red pixel R may be approximately twice the width P₁ of the green pixel G.

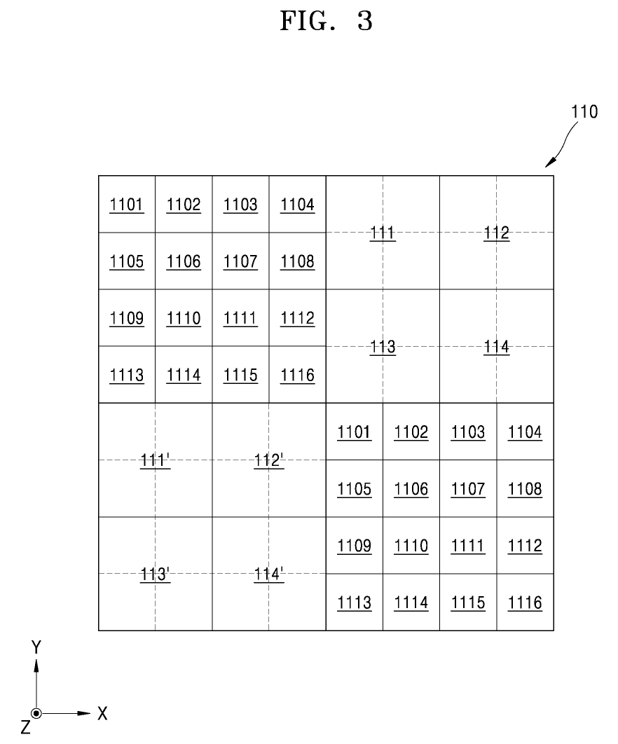

FIG. 3 is a plan view schematically showing an arrangement of a sensor substrate provided in a pixel array of an image sensor according to an embodiment.

Referring to FIG. 3, a plurality of pixels of the pixel array 1100 may be defined by a device isolation film, and each of the plurality of pixels separated by the device isolation film may include a light sensing cell provided on the sensor substrate 110. For example, the sensor substrate 110 may include a plurality of light sensing cells 1101 to 1116 in a 4×4 arrangement provided in each of the first unit pixel 1100G₁ and the fourth unit pixel 1100G₄. The plurality of light sensing cells 1101 to 1116 provided in each of the first unit pixel 1100G₁ and the fourth unit pixel 1100G₄ may be used as independent image signal generation pixels. In addition, the sensor substrate 110 may include a plurality of light sensing cells 111, 112, 113, and 114 or 111′, 112′, 113′, and 114′ in a 2×2 arrangement provided in each of the second unit pixel 1100G₂ and the third unit pixel 1100G₃. The plurality of light sensing cells 111, 112, 113, and 114 or 111’, 112’, 113’, and 114’ arranged in a 2×2 arrangement in each of the second unit pixel 1100G₂ and the third unit pixel 1100G₃ may be used as image signal generating pixels and may also be used as auto focus signal generating pixels. For example, signals generated by the light sensing cell 111 (e.g., a first light sensing cell) and the light sensing cell 112 (e.g., a second light sensing cell) provided side by side in the first direction (e.g., X-direction) may be used to perform the auto-focus function using a horizontal phase difference of the incident light, and signals generated by the light sensing cell 111 (e.g., the first light sensing cell) and the light sensing cell 113 (e.g., a third light sensing cell) provided side by side in the second direction (e.g., Y-direction) may be used to perform the auto-focus function using a vertical phase difference of the incident light.

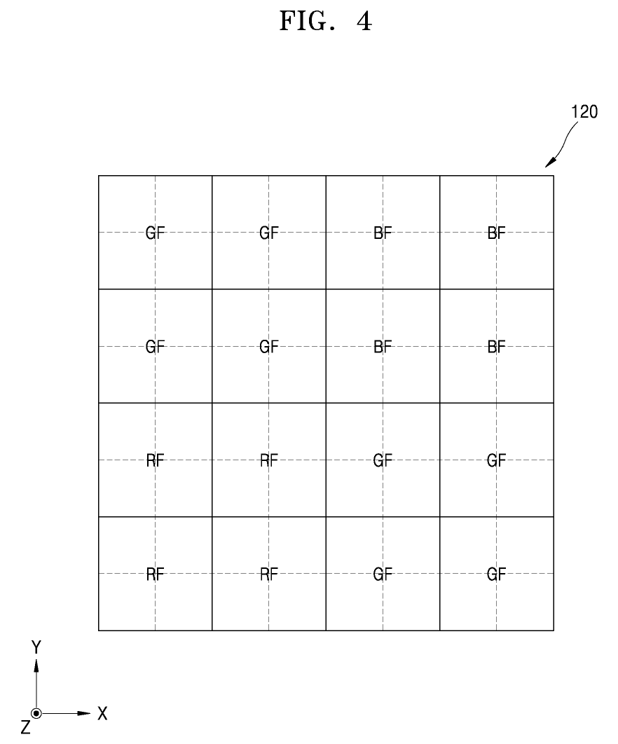

FIG. 4 is a plan view schematically showing an arrangement of a color filter array provided in a pixel array of an image sensor according to an embodiment.

Referring to FIG. 4, the image sensor 1000 may include a color filter array 120. The color filter array 120 may be provided on the sensor substrate 110. The color filter array 120 may be selectively provided to increase color purity. The color filter array 120 may include a plurality of color filters (e.g., green color filters GF, blue color filters BF, and red color filters RF), and each of the plurality of color filters (e.g., the green color filters GF, the blue color filters BF, and the red color filters RF) may correspond to at least one pixel. For example, each green color filter GF may be provided to respectively correspond to (e.g., overlap with) the 2×2 arrangement green pixels G provided in the first unit pixel 1100G₁ and the fourth unit pixel 1100G₄, blue color filters BF may be provided to respectively correspond to (e.g., overlap with) the blue pixels B provided in the second unit pixel 1100G₂, and red color filters RF may be provided to respectively correspond to (e.g., overlap with) the red pixels R provided in the third unit pixel 1100G₃.

The green color filter GF may transmit light in a green wavelength band among incident light, the blue color filter BF may transmit light in a blue wavelength band among incident light, and the red color filter RF may transmit light in a red wavelength band among incident light. These color filters may be organic color filters including organic dyes or organic pigments, and the color filters (e.g., the green color filters GF, the blue color filters BF, and the red color filters RF) may have an arrangement different from the color filter arrangement shown in FIG. 4, or may be omitted.

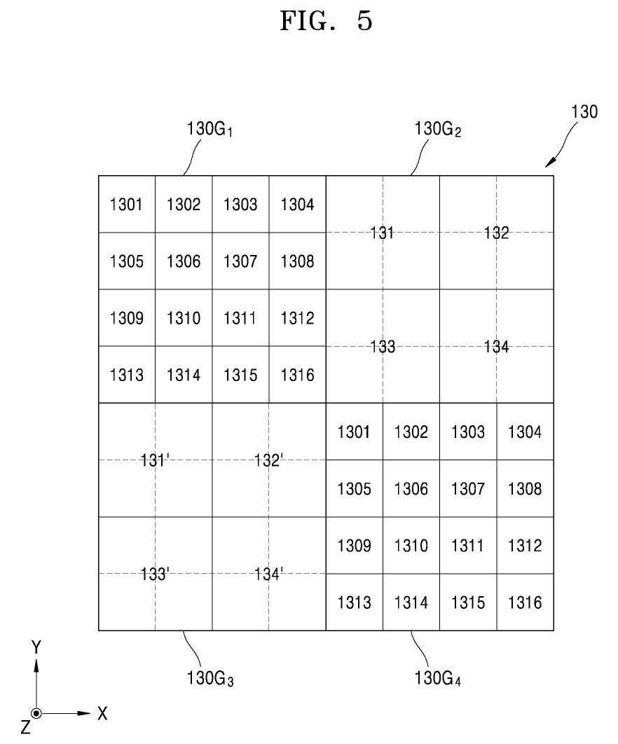

FIG. 5 is a plan view schematically showing an arrangement of a nano-photonic microlens array provided in a pixel array of an image sensor according to an embodiment.

Referring to FIG. 5, a nano-photonic microlens array 130 may include a plurality of pixel corresponding regions, and nanostructures may be provided in each region. The division of the regions of the nano-photonic microlens array 130 and the shape and arrangement of the nanostructures provided in each region may be set to form a phase distribution that causes incident light to be separated by wavelength and focused onto pixels facing each other. In the following description, color separation in the visible light band will be described, but is not limited thereto, and the wavelength band may be extended to a range of visible light to infrared light, or various other ranges.

The nano-photonic microlens array 130 may include a plurality of unit pixel corresponding regions (e.g., a first unit pixel corresponding region 130G₁, a second unit pixel corresponding region 130G₂, a third unit pixel corresponding region 130G₃, and a fourth unit pixel corresponding region 130G₄) respectively corresponding to (e.g., overlapping with) the plurality of unit pixels (e.g., the first unit pixel 1100G₁, the second unit pixel 1100G₂, the third unit pixel 1100G₃, and the fourth unit pixel 1100G₄) of the sensor substrate 110 shown in FIG. 3. The first unit pixel corresponding region 130G₁ may be provided to face the first unit pixel 1100G₁, the second unit pixel corresponding region 130G₂ may be provided to face the second unit pixel 1100G₂, the third unit pixel corresponding region 130G₃ may be provided to face the third unit pixel 1100G₃, and the fourth unit pixel corresponding region 130G₄ may be provided to face the fourth unit pixel 1100G₄.

Incident light may be focused on pixels provided on the sensor substrate 110 according to the shape and arrangement of a plurality of nanostructures provided in each of the first to fourth unit pixel corresponding regions 130G₁, 130G₂, 130G₃, and 130G₄.

For example, the first unit pixel corresponding region 130G₁ and the fourth unit pixel corresponding region 130G₄ may be configured such that incident light is respectively focused on 16 green pixels G provided in each of the first unit pixel 1100G₁ and the fourth unit pixel 1100G₄. Further, the second unit pixel corresponding region 130G₂ may be arranged such that the incident light is respectively focused on each of the four blue pixels B provided in the second unit pixel 1100G₂, and the third unit pixel corresponding region 130G₃ may be configured such that the incident light is respectively focused on each of the four red pixels R provided in the third unit pixel 1100G₃.

The first unit pixel corresponding region 130G₁ and the fourth unit pixel corresponding region 130G₄ may include a plurality of green pixel corresponding regions 1301 to 1316 configured such that incident light is respectively focused on the plurality of green pixels G provided in each of the first unit pixel 1100G₁ and the fourth unit pixel 1100G₄. In addition, the second unit pixel corresponding region 130G₂ may include a plurality of blue pixel corresponding regions 131 to 134 configured to respectively focus incident light on the plurality of blue pixels B provided in the second unit pixel 1100G₂, and the third unit pixel corresponding region 130G₃ may include a plurality of red pixel corresponding regions 131’ to 134’ configured to respectively focus incident light on the plurality of red pixels R provided in the third unit pixel 1100G₃.

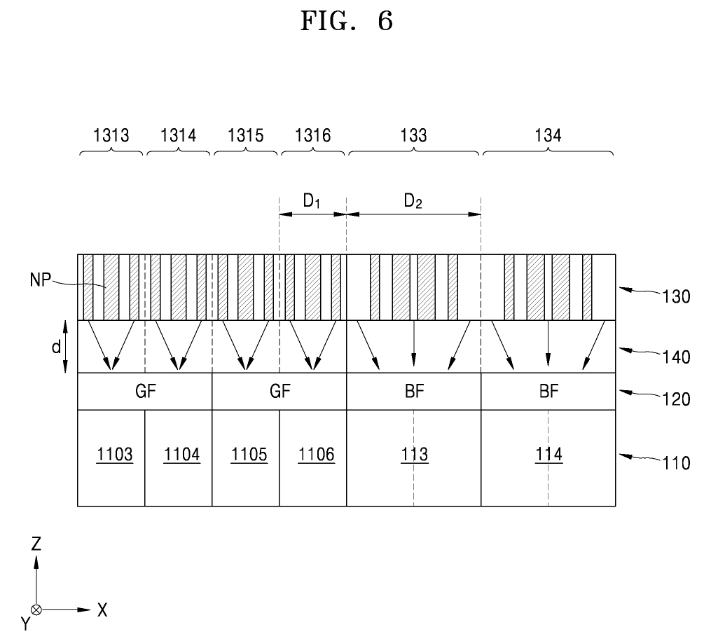

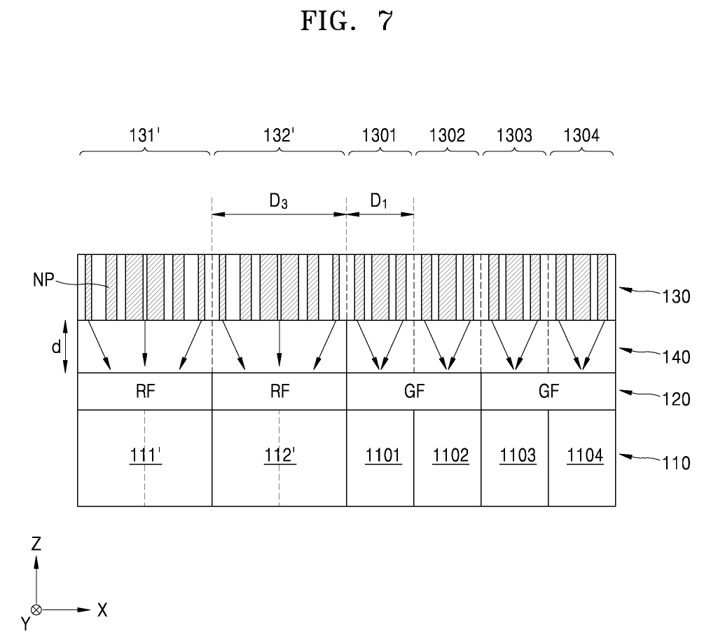

FIGS. 6 and 7 are cross-sectional views schematically showing the configuration of a pixel array 1100 of the image sensor 1000 according to an embodiment, respectively, in different cross-sections. FIG. 6 shows a cross section of the pixel array 1100 of FIG. 2 taken along the line A-A’, and FIG. 7 shows a cross section of the pixel array 1100 of FIG. 2 taken along the line B-B’.

Referring to FIGS. 6 and 7, the pixel array 1100 of the image sensor 1000 may include a sensor substrate 110, a color filter array 120 arranged on the sensor substrate 110, and a nano-photonic microlens array 130 disposed on the color filter array 120. The sensor substrate 110 and the color filter array 120 have been described with reference to FIGS. 3 and 4, respectively, and thus a repeated description thereof may be omitted.

The nano-photonic microlens array 130 may include a plurality of nanostructures NP. The nano-photonic microlenses having effective diameters of different sizes for each color may be formed by the plurality of nanostructures NP provided in the nano-photonic microlens array 130. The plurality of green pixel corresponding regions 1301 to 1316 provided in each of the first unit pixel corresponding region 130G₁ and the fourth unit pixel corresponding region 130G₄ may each form a respective nano-photonic microlens from among a plurality of nano-photonic microlenses each having an effective diameter D₁. The plurality of regions 131 to 134 provided in the second unit pixel corresponding region 130G₂ may each form a respective nano-photonic microlens from among a plurality of nano-photonic microlenses each having an effective diameter D₂. The plurality of regions 131’ to 134’ provided in the third unit pixel corresponding region 130G₃ may each form a respective nano-photonic microlens from among a plurality of nano-photonic microlenses each having an effective diameter D₃. Here, diameters D₂ or D₃ may be approximately twice as large as diameter D₁.

Incident light may be focused in the unit pixels (e.g., the first unit pixel 1100G₁, the second unit pixel 1100G₂, the third unit pixel 1100G₃, and the fourth unit pixel 1100G₄) according to the shape and arrangement of the nanostructures NP. For example, incident light may be respectively focused on a plurality of light sensing cells 1101 to 1116 of each of the first unit pixel 1100G₁ and the fourth unit pixel 1100G₄, incident light may be respectively focused on a plurality of light sensing cells 111 to 114 of the second unit pixel 1100G₂, and incident light may be respectively focused on a plurality of light sensing cells 111′ to 114′ provided in the third unit pixel 1100G₃.

In other words, the arrangement of nanostructures in the first to fourth unit pixel corresponding regions 130G₁, 130G₂, 130G₃, and 130G₄ may be set so that a phase distribution suitable for this condensing distribution is formed at a position immediately after the incident light passes through the nano-photonic microlens array 130. The plurality of nanostructures NP provided in the nano-photonic microlens array 130 may be arranged according to a specific rule to form different phase distributions for light of a plurality of wavelengths. Here, the rule may include parameters such as shape, size (e.g., width, height), spacing, and arrangement shape of the nanostructure NP, and these parameters may be determined according to a phase profile to be implemented through the nano-photonic microlens array 130.

The nanostructure NP may have a shape dimension of a sub-wavelength. Here, the sub-wavelength means a wavelength band smaller than a wavelength band of light to be branched. The nanostructure NP may have a cylindrical shape having a cross-sectional diameter of a sub-wavelength. However, the shape of the nanostructure NP is not limited thereto, and may be an elliptical column or a polygonal column. The nanostructures NP may have post shapes having other symmetrical or asymmetric cross-sectional shapes. The nanostructures NP may have a cross-section having a constant width, which is perpendicular to the height direction (Z-direction), that is, a rectangular cross-section parallel to the height direction, but this is merely an example. According to some example embodiments of the disclosure, the nanostructures NP may not have a constant width perpendicular to the height direction, and for example, a cross-section parallel to the height direction may have a trapezoidal or inverse trapezoidal shape. When the incident light is visible light, the diameter of a cross-section of the nanostructure NP may have dimensions less than, for example, 400 nm, 300 nm, or 200 nm. Meanwhile, the heights of the nanostructures NP may be 500 nm to 1500 nm, and the heights may be greater than the diameters of the cross sections. The heights of the nanostructures NP may amount to several times a sub-wavelength or wavelength. For example, the heights of the nanostructures NP may have five times or less, four times or less, or three times or less as large as the center wavelength of the wavelength band in which the nano-photonic microlens array 130 branches. All of the nanostructures NP are shown at the same height, but are not limited thereto. The details of the nanostructure NP may be determined in consideration of the detailed process conditions, together with the phase distribution for condensing.

The space between the nanostructures NP may be filled with a peripheral material that has a different refractive index from refractive indexes of the nanostructures NP. The nanostructure NP may include a material having a refractive index higher than a refractive index of a peripheral material. For example, the nanostructure NP may include c-Si, p-Si, a-Si, and group III-V compound semiconductors (e.g., GaP, GaN, GaAs, etc.), SiC, TiO₂, SiN, and/or combinations thereof. The nanostructure NP having a refractive index difference from the peripheral material may change a phase of light passing through the nanostructure NP. This is due to phase delay caused by the shape dimension of the sub-wavelengths of the nanostructures NP, and the degree of phase delay may be determined by the detailed shape dimension and arrangement shape of the nanostructures NP. The peripheral material of each of the nanostructures NP may include a dielectric material having a lower refractive index than a refractive index of each of the nanostructures NP. For example, the peripheral material may include SiO₂ or air. However, this is merely an example, and materials of the nanostructure NP and the peripheral material may be set such that the nanostructure NP has a refractive index lower than a refractive index of the peripheral material.

A spacer layer 140 (e.g., a transparent spacer layer) may be disposed between the sensor substrate 110 and the nano-photonic microlens array 130. The spacer layer 140 may support the nano-photonic microlens array 130, and may have a thickness that satisfies a distance d between the sensor substrate 110 and the nano-photonic microlens array 130, that is, a distance between the top surface of the sensor substrate 110 and the bottom surface of the nano-photonic microlens array 130.

The spacer layer 140 may include a material that is transparent to visible light such as, for example, a dielectric material that has a lower refractive index than a refractive index of the nanostructure NP such as SiO₂, siloxane-based spin on glass (SOG) and has a lower absorption rate in the visible light band. When the peripheral material layer filled between the nanostructures NP includes a material having a higher refractive index than refractive indexes of the nanostructures NP, the spacer layer 140 may include a material having a lower refractive index than a refractive index of the peripheral material layer. The distance d between the bottom surface of the nano-photonic microlens array 130 and the top surface of the sensor substrate 110 may be determined based on the focal length of light concentrated by the nano-photonic microlens array 130.

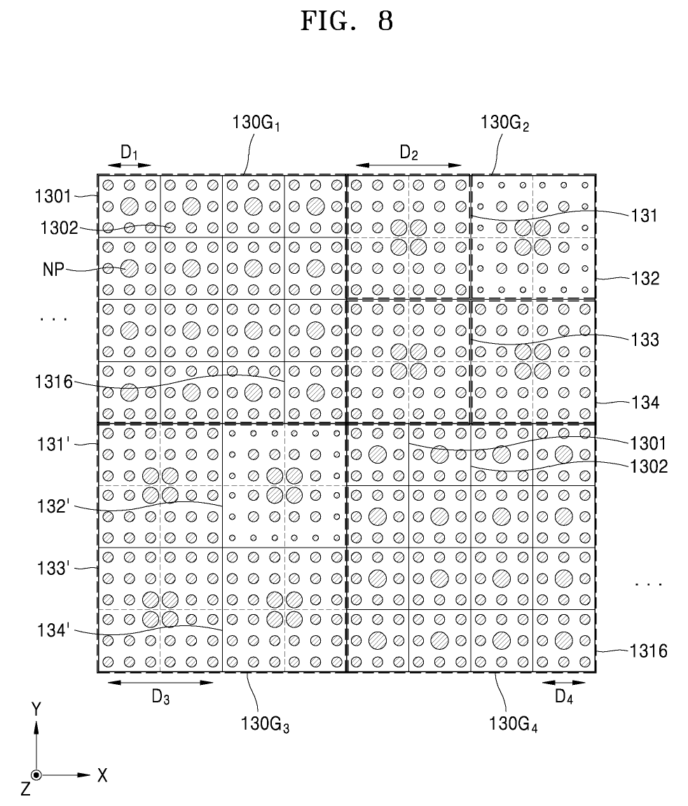

FIG. 8 is a plan view illustrating an arrangement of nanostructures NP included in a nano-photonic microlens array 130 according to an embodiment.

Referring to FIG. 8, a plurality of nanostructures NP may be provided in each of the pixel corresponding regions (e.g., the first unit pixel corresponding region 130G₁, the second unit pixel corresponding region 130G₂, the third unit pixel corresponding region 130G₃, and the fourth unit pixel corresponding region 130G₄) of the nano-photonic microlens array 130 to form nano-photonic microlenses having different effective diameters for respective colors of light sensed by pixels corresponding to respective regions.

For example, as described above, a plurality of nanostructures NP may be provided to form a plurality of nano-photonic microlenses each having an effective diameter D₁, in each of the plurality of green pixel corresponding regions 1301 to 1316 provided in each of the first unit pixel corresponding region 130G₁ and the fourth unit pixel corresponding region 130G₄ corresponding to the plurality of green pixels G. In addition, a plurality of nanostructures NP may be provided to form a plurality of nano-photonic microlenses each having an effective diameter D₂ in a plurality of blue pixel corresponding regions 131 to 134 provided in the second unit pixel corresponding region 130G₂ corresponding to the plurality of blue pixels B. In addition, a plurality of nanostructures NP may be provided to form a plurality of nano-photonic microlenses each having an effective diameter D₃ in a plurality of red pixel corresponding regions 131’ to 134’ provided in the third unit pixel corresponding region 130G₃ corresponding to the plurality of blue pixels R.

For example, a plurality of nanostructures NP provided in the first unit pixel corresponding region 130G₁ and the fourth unit pixel corresponding region 130G₄ corresponding to the plurality of green pixels G may be provided in a 3×3 arrangement within each of the green pixel corresponding regions 1301 to 1316. A nanostructure NP having the largest diameter may be provided at the center of each of the green pixel corresponding regions 1301 to 1316, and a nanostructure NP having a relatively small diameter may be provided at the edge of each of the green pixel corresponding regions 1301 to 1316. According to the arrangement of the nanostructures NP, a nano-photonic microlens having an effective diameter D₁ may be formed in each of the green pixel corresponding regions 1301 to 1316.

In addition, the plurality of nanostructures NP provided in the second unit pixel corresponding region 130G₂ corresponding to the plurality of blue pixels B may be provided in a 6×6 arrangement within each of the blue pixel corresponding regions 131 to 134. A nanostructure NP having the largest diameter may be provided at the center of each of the blue pixel corresponding regions 131 to 134, and a nanostructure NP having a relatively smaller diameter may be provided toward the edge of each of the blue pixel corresponding regions 131 to 134. According to the arrangement of the nanostructures NP, a nano-photonic microlens having an effective diameter D₂ may be formed in each of the blue pixel corresponding regions 131 to 134.

Likewise, the plurality of nanostructures NP provided in the third unit pixel corresponding region 130G₃ corresponding to the plurality of red pixels R may be provided in a 6×6 arrangement within each of the red pixel corresponding regions 131’ to 134’. A nanostructure NP having the largest diameter may be provided at the center of each of the red pixel corresponding regions 131’ to 134’, and a nanostructure NP having a relatively smaller diameter may be provided toward the edge of each of the red pixel corresponding regions 131’ to 134’. According to the arrangement of the nanostructures NP, a nano-photonic microlens having an effective diameter D₃ may be formed in each of the red pixel corresponding regions 131’ to 134’. Here, the effective diameter D₂ and/or the effective diameter D₃ may be different from the effective diameter D₁, and the effective diameter D₂ and/or the effective diameter D₃ may be approximately twice as large as the effective diameter D1.

In other words, a nanostructure with the largest diameter may be provided at the center of each of the plurality of pixel corresponding regions (e.g., green pixel corresponding regions 1301 to 1316, blue pixel corresponding regions 131 to 134, and red pixel corresponding regions 131’ to 134’). The distance from the center of the nanostructure NP having the largest diameter in each of the green pixel corresponding regions 1301 to 1316 to the boundary of each of the green pixel corresponding regions 1301 to 1316 in which the corresponding nanostructure NP is provided may be less than the distance from the center of the nanostructure NP having the largest diameter in each of the blue pixel corresponding regions 131 to 134 or red pixel corresponding regions 131’ to 134′ to the boundary of each of the pixel corresponding regions in which the corresponding nanostructure NP is provided. The distance from the center of the nanostructure NP having the largest diameter in each pixel corresponding region in the blue pixel corresponding regions 131 to 134 and/or the red pixel corresponding regions 131’ to 134’ to the boundary thereof may be approximately twice as large as the distance from the center of the nanostructure NP having the largest diameter in each of the green pixel corresponding regions 1301 to 1316 to the boundary thereof.

However, the arrangement of the nanostructures NP shown in FIG. 8 is illustrated only as an example, and the nanostructures NP may be provided in various arrangements according to the phase profile to be implemented. For example, a nanostructure NP having the largest diameter may be provided at the center of each of the green pixel corresponding regions 1301 to 1316, and the diameters of the nanostructures NP may gradually decrease toward the edge of each of the green pixel corresponding regions 1301 to 1316, and then a nanostructure NP with relatively large diameter may be provided.

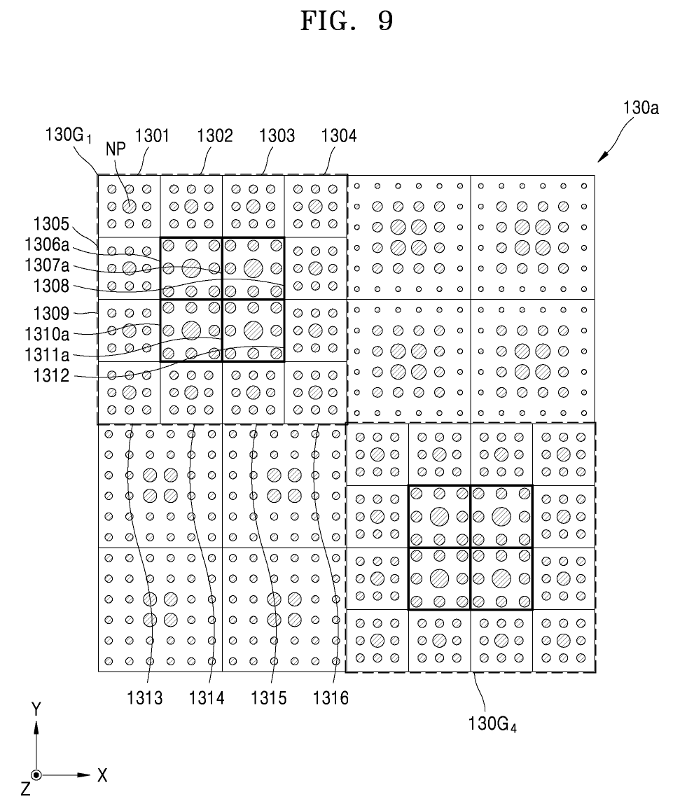

FIG. 9 is a plan view illustrating an arrangement of nanostructures NP included in a nano-photonic microlens array 130a according to an embodiment. Differences from FIG. 8 are mainly described with reference to FIG. 9.

Referring to FIG. 9, the arrangement of the plurality of nanostructures NP provided in the first unit pixel corresponding region 130G₁ and the fourth unit pixel corresponding region 130G₄ corresponding to the plurality of green pixels G may be configured to be different from the green pixel corresponding regions 1306a, 1307a, 1310a, and 1311a provided in the center of each of the first unit pixel corresponding region 130G₁ and the fourth unit pixel corresponding region 130G₄ and the green pixel corresponding regions 1301, 1302, 1303, 1304, 1305, 1308, 1309, 1312, 1313, 1314, 1315, and 1316 provided in the peripheral portions thereof.

For example, the diameters of the plurality of nanostructures NP provided in the green pixel corresponding regions 1306a, 1307a, 1310a, and 1311a provided in the center of each of the first unit pixel corresponding region 130G₁ and the fourth unit pixel corresponding region 130G₄ may be generally larger than the diameters of the plurality of nanostructures NP provided in the green pixel corresponding regions 1301, 1302, 1303, 1304, 1305, 1308, 1309, 1312, 1313, 1314, 1315, and 1316 provided in the peripheral portions thereof.

As described above, since the arrangement of the plurality of nanostructures NP provided in the regions provided in the central portions of the first unit pixel corresponding region 130G₁ and the fourth unit pixel corresponding region 130G₄ is configured to be different from the arrangement of the plurality of nanostructures NP provided in the regions provided in the peripheral portions of the first unit pixel corresponding region 130G₁ and the fourth unit pixel corresponding region 130G₄, the difference in curvatures of the lenses formed by the plurality of nanostructures NP between the central portions and the peripheral portions of each of the first unit pixel corresponding region 130G₁ and the fourth unit pixel corresponding region 130G₄ is configured to occur, and thus the light condensing efficiency may be adjusted, and accordingly, the light utilization efficiency of the image sensor 1000 may be improved.

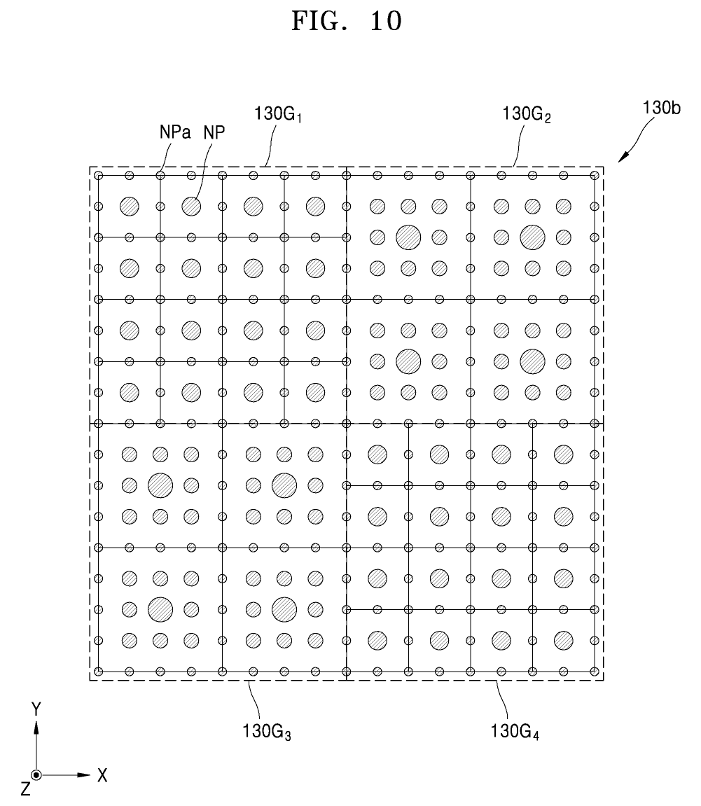

FIG. 10 is a plan view illustrating an arrangement of nanostructures NP and NPa included in a nano-photonic microlens array 130b according to an embodiment. Differences from FIG. 8 are mainly described with reference to FIG. 10.

Referring to FIG. 10, a plurality of pixel corresponding regions provided in each of the unit pixel corresponding regions (e.g., the first unit pixel corresponding region 130G₁, the second unit pixel corresponding region 130G₂, the third unit pixel corresponding region 130G₃, and the fourth unit pixel corresponding region 130G₄) may include nanostructures NPa provided at a boundary of each pixel corresponding region. The nanostructures NPa provided at the boundary of each pixel corresponding region may be provided to be spaced apart from each other at a predetermined interval along the boundary of each region. The nanostructures NPa provided at the boundary of each pixel corresponding region may be shared between adjacent regions. A plurality of nanostructures NP having an N×N arrangement (where N is the natural number) may be provided inside the boundary of each pixel corresponding region.

By providing the nanostructures NPa at the boundary of each pixel corresponding region, the interval (e.g., period) of the plurality of nanostructures NP and NPa may be designed to be larger, and the size change of the nanostructures NP and NPa may be possible in a wider range, thereby increasing the degree of freedom in design of the plurality of nanostructures NP and NPa.

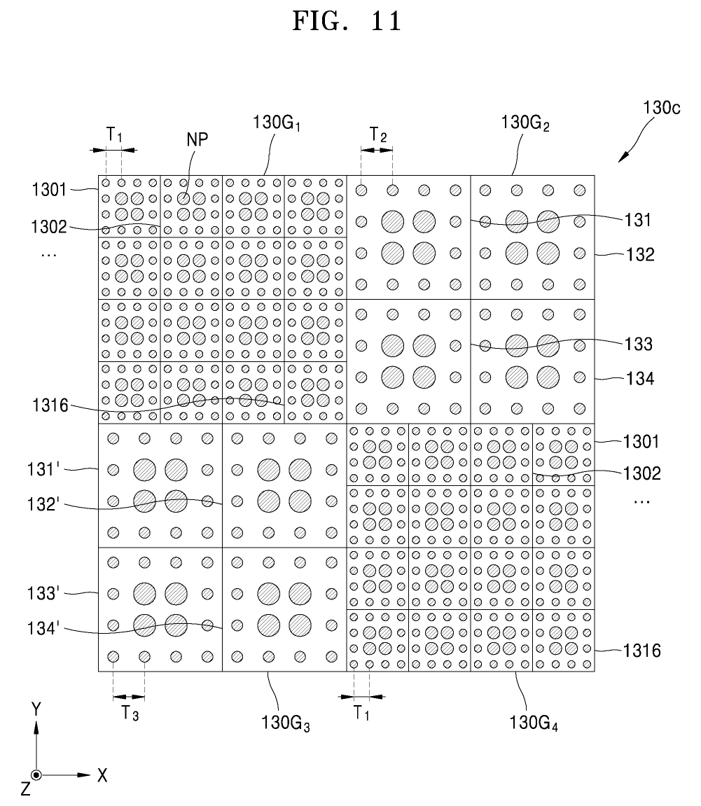

FIG. 11 is a plan view illustrating an arrangement of nanostructures NP included in a nano-photonic microlens array 130c according to an embodiment. Differences from FIG. 8 are mainly described with reference to FIG. 9.

Referring to FIG. 8, a plurality of nanostructures NP may be provided in each of the pixel corresponding regions (e.g., the first unit pixel corresponding region 130G₁, the second unit pixel corresponding region 130G₂, the third unit pixel corresponding region 130G₃, and the fourth unit pixel corresponding region 130G₄) of the nano-photonic microlens array 130c to have different arrangements (e.g., the periods) for respective colors of light sensed by pixels corresponding to respective regions.

For example, periods T₁ and T₄ in which a plurality of nanostructures NP provided in the green pixel corresponding regions 1301 to 1316 are arranged may be different from periods T₂ and T₃ in which a plurality of nanostructures NP provided in the blue pixel corresponding regions 131 to 134 and the red pixel corresponding regions 131’ to 134’ are arranged. For example, the periods T₂ of the plurality of nanostructures NP provided in the blue pixel corresponding regions 131 to 134 and/or the periods T₃ of the plurality of nanostructures NP provided in the red pixel corresponding regions 131’ to 134’ may be approximately twice the periods T₁ and T₄ of the plurality of nanostructures NP provided in the green pixel corresponding regions 1301 to 1316. Here, the period of the nanostructures NP may mean an interval from the center of each nanostructure NP to the center of the closest nanostructure NP.

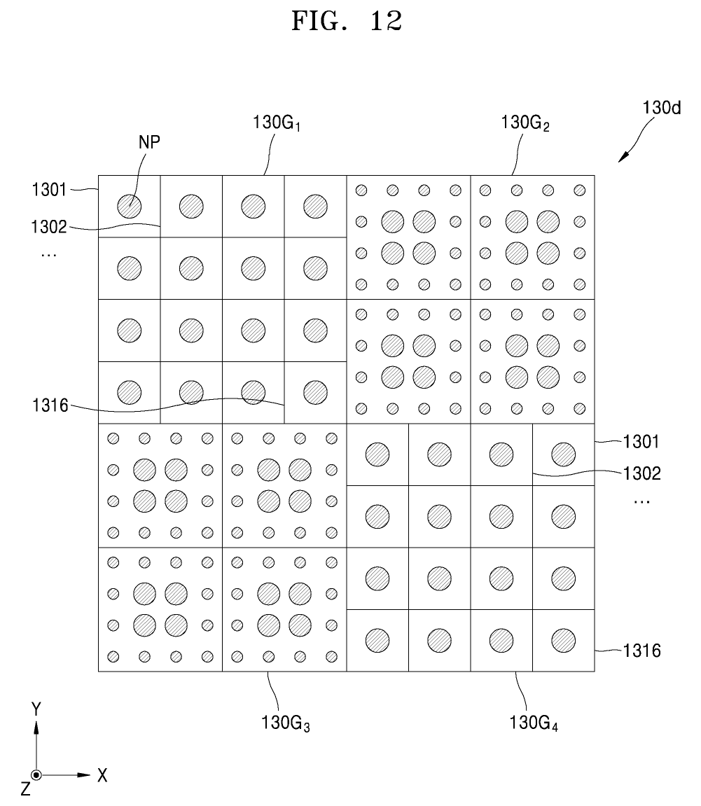

FIG. 12 is a plan view illustrating an arrangement of nanostructures NP included in a nano-photonic microlens array 130d according to an embodiment. Differences from FIG. 11 are mainly described with reference to FIG. 12.

Referring to FIG. 12, one nanostructure NP may be provided at the center of each of a plurality of green pixel corresponding regions 1301 to 1316. That is, a total of 16 nanostructures NP may be provided in each of the first unit pixel corresponding region 130G₁ and the fourth unit pixel corresponding region 130G₄ by arranging one nanostructure NP in each of the green pixel corresponding regions 1301 to 1316.

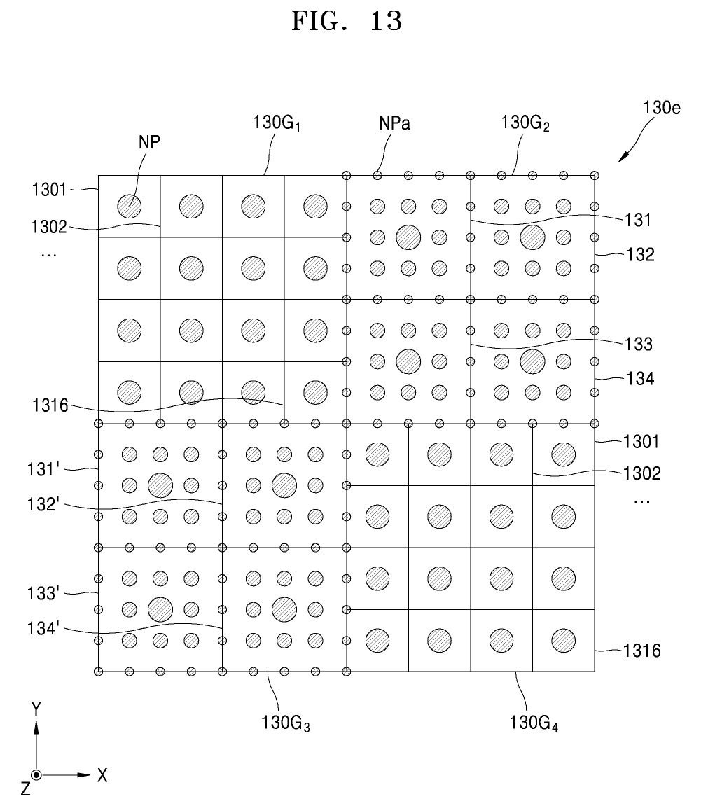

FIG. 13 is a plan view illustrating an arrangement of nanostructures NP included in a nano-photonic microlens array 130e according to an embodiment. Differences from FIG. 12 are mainly described with reference to FIG. 13.

Referring to FIG. 13, a nanostructure NP may be provided at the center of each of the green pixel corresponding regions 1301 to 1316, and nanostructures NPa may be provided at the boundary of each pixel corresponding region in the plurality of blue pixel corresponding regions 131 to 134 and the plurality of red pixel corresponding regions 131’ to 134’.

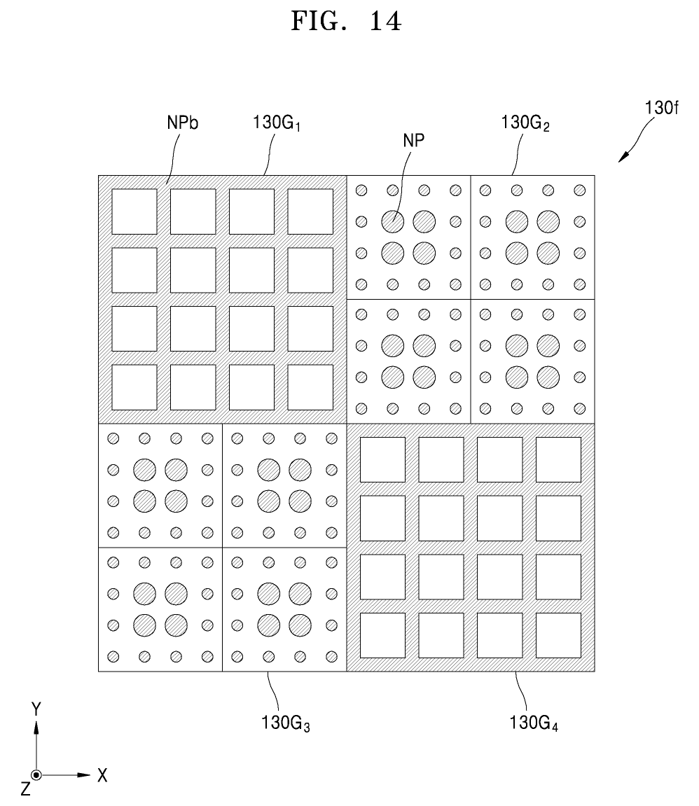

FIG. 14 is a plan view illustrating an arrangement of nanostructures NP included in a nano-photonic microlens array 130f according to an embodiment. Differences from FIG. 11 are mainly described with reference to FIG. 14.

Referring to FIG. 14, a plurality of nanostructures NPb in the form of a grid extending in the first direction (e.g., X direction) and the second direction (e.g., Y direction), respectively, may be provided in the plurality of green pixel corresponding regions 1301 to 1316, along the boundary of each pixel corresponding region. Like the nanostructure NP described above, the plurality of nanostructures NPb in the form of a grid may condense green light to a plurality of light sensing cells 1101 to 1116 provided in the first unit pixel 1100G₁ and the fourth unit pixel 1100G₄.

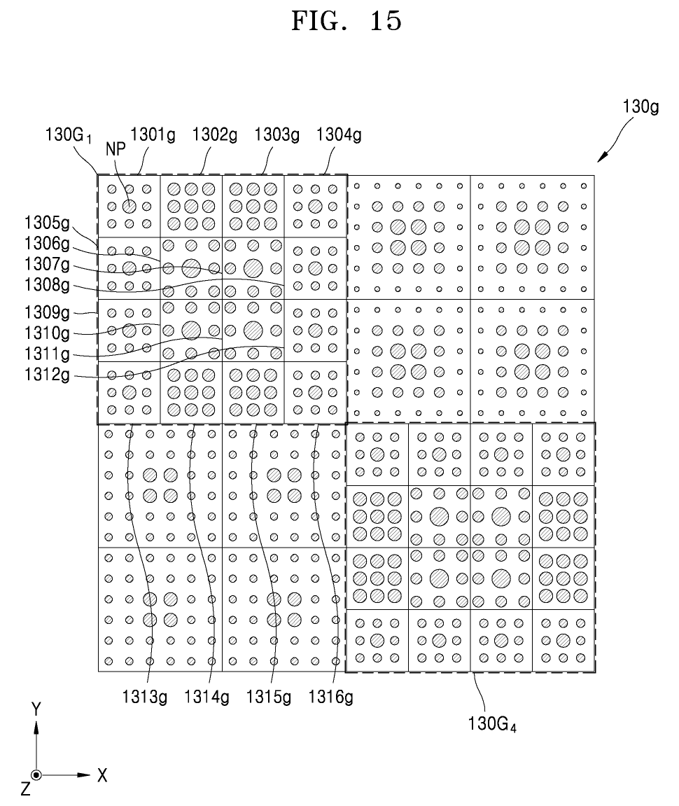

FIG. 15 is a plan view illustrating an arrangement of nanostructures NP included in a nano-photonic microlens array 130g according to an embodiment. Differences from FIG. 9 are mainly described with reference to FIG. 15. Hereinafter, for convenience, the green pixel corresponding regions 1306g, 1307g, 1310g, and 1311g provided in the central portion of the first unit pixel corresponding region 130G₁ and the fourth unit pixel corresponding region 130G₄ corresponding to the plurality of green pixels G may be referred to as central regions. The green pixel corresponding regions 1305g, 1308g, 1309g, and 1312g adjacent in the first direction (e.g., X direction) to the central regions (e.g., the green pixel corresponding regions 1306g, 1307g, 1310g, and 1311g) among the peripheral portions of the first unit pixel corresponding region 130G₁ and the fourth unit pixel corresponding region 130G₄ corresponding to the plurality of green pixels G, may be referred to as the first direction peripheral regions. The green pixel corresponding regions 1302g, 1303g, 1314g, and 1315g adjacent in the second direction (e.g., Y direction) to the central regions (e.g., the green pixel corresponding regions 1306g, 1307g, 1310g, and 1311g) among the peripheral portions of the first unit pixel corresponding region 130G₁ and the fourth unit pixel corresponding region 130G₄ corresponding to the plurality of green pixels G, may be referred to as second direction peripheral regions.

Referring to FIG. 15, the arrangement of the plurality of nanostructures NP provided in the first direction peripheral regions (e.g., the green pixel corresponding regions 1305g, 1308g, 1309g, and 1312g) of each of the first unit pixel corresponding region 130G₁ and the fourth unit pixel corresponding region 130G₄ corresponding to the plurality of green pixels G may be configured to be different from the arrangement of the plurality of nanostructures NP provided in the second direction peripheral regions (e.g., the green pixel corresponding regions 1302g, 1303g, 1314g, and 1315g).

For example, the diameters of the plurality of nanostructures NP provided in the second-direction peripheral regions (e.g., the green pixel corresponding regions 1302g, 1303g, 1314g, and 1315g) may be generally greater than the diameters of the plurality of nanostructures NP provided in the first-direction peripheral regions (e.g., the green pixel corresponding regions 1305g, 1308g, 1309g, and 1312g). For example, the diameter of a nanostructure having the largest diameter among a plurality of nanostructures NP provided in the second direction peripheral regions (e.g., the green pixel corresponding regions 1302g, 1303g, 1314g, and 1315g) may be greater than the diameter of a nanostructure having the largest diameter among a plurality of nanostructures NP provided in the first direction peripheral regions (e.g., the green pixel corresponding regions 1305g, 1308g, 1309g, and 1312g), and the diameter of a nanostructure having the smallest diameter among a plurality of nanostructures NP provided in the second direction peripheral regions (e.g., the green pixel corresponding regions 1302g, 1303g, 1314g, and 1315g) may be greater than the diameter of a nanostructure having the smallest diameter among a plurality of nanostructures NP provided in the first direction peripheral regions (e.g., the green pixel corresponding regions 1305g, 1308g, 1309g, and 1312g).

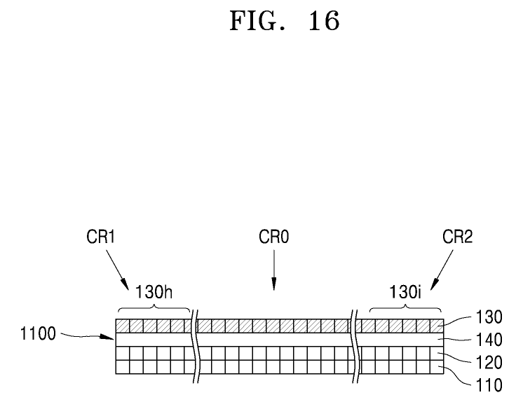

FIG. 16 is a plan view illustrating a pixel array according to a chief ray angle according to an embodiment.

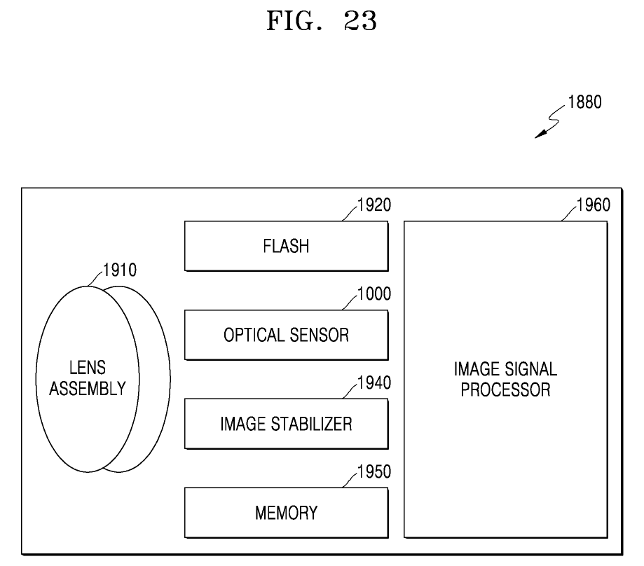

An incident angle of light incident on the pixel array 1100 is generally defined as a chief ray angle (CRA). The chief ray may refer to a ray incident on the pixel array 1100 after passing through the center of a lens assembly 1910 (see FIG. 23) from a point of a subject, and the chief ray angle CRA may refer to an angle formed by the chief ray with respect to an optical axis. Light starting from a point on the optical axis may have a chief light angle of 0° and is incident perpendicular to the pixel array 1100. As the starting point is farther away from the optical axis, the CRA may increase.

From the viewpoint of the image sensor 1000, a chief ray angle CR0 of the light incident on the nano-photonic microlens array 130 provided at the central portion of the pixel array 1100 may be 0 degrees, and the chief ray angles CR1 and CR2 of incident light incident on the peripheral portions 130h and 130i of the nano-photonic microlens array increase toward the edge of the pixel array 1100. As described above, the chief ray angle CRA of incident light incident on the pixels varies according to the positions of the pixels in the pixel array 1100, and thus optical characteristics such as pixel sensitivity may change according to the positions of the pixels. In addition, even if the chief ray angle is the same, the optical characteristics of the pixels may change if the azimuthal angle varies depending on the locations of the pixels. As described above, the unit lenses constituting the nano-photonic microlens array may be designed so that the optical characteristics of the pixels are not changed according to changes in the chief ray angle and the azimuthal angle. Hereinafter, the arrangement of nanostructures provided in the peripheral regions (e.g., the peripheral portions 130h and 130i) of the nano-photonic microlens array is described.

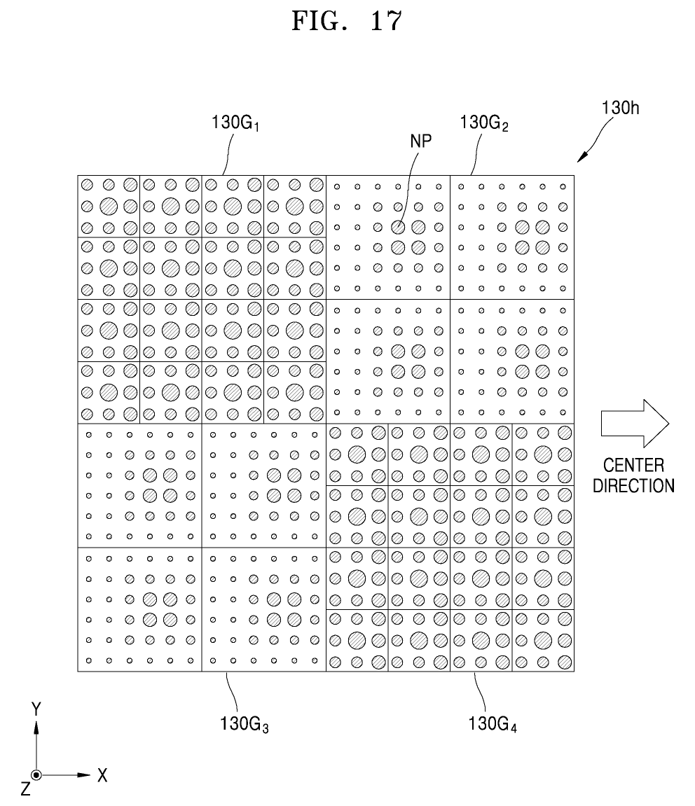

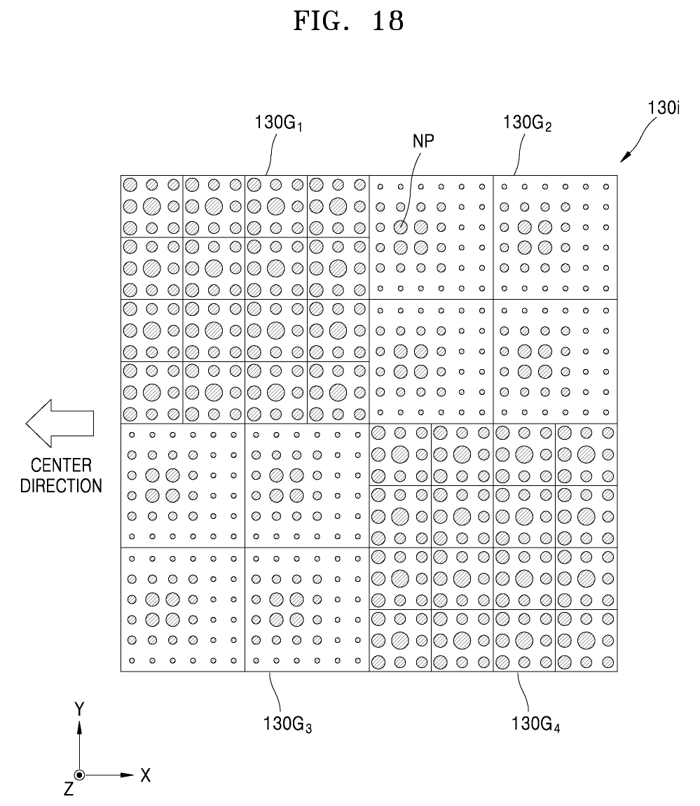

FIGS. 17 and 18 are plan views illustrating an arrangement of nanostructures included in a peripheral portion of a nano-photonic microlens array 130 according to an embodiment.

Referring to FIGS. 17 and 18, the arrangement of a plurality of nanostructures NP provided at the peripheral portions 130h and 130i of the nano-photonic microlens array 130 may be shifted toward the center direction. For example, a nanostructure NP having the largest diameter in each pixel corresponding region provided in the peripheral portions 130h and 130i of the nano-photonic microlens array 130 may be shifted from the central portion of the pixel corresponding region in the center direction of the nano-photonic microlens array 130. As the chief ray angle of incident light incident on the peripheral portions 130h and 130i of the nano-photonic microlens array 130 increases, the shifted distance of the arrangements of the plurality of nanostructure NP provided on the peripheral portions 130h and 130i of the nano-photonic microlens array 130 may increase. Although FIGS. 17 and 18 illustrate only that the arrangement of the plurality of nanostructures NP is shifted in the first direction (e.g., X direction) for convenience, the arrangement of the plurality of nanostructures NP may be shifted according to the incident direction of the chief ray.

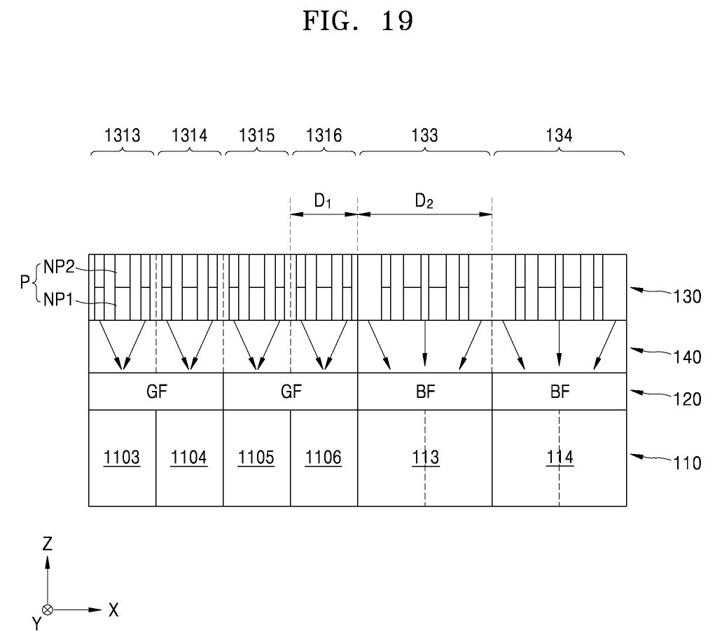

FIG. 19 is a cross-sectional view taken along the line A-A’ of FIG. 2 according to an embodiment. Differences from FIG. 6 are mainly described with reference to FIG. 19.

Referring to FIG. 19, a plurality of nanostructures NP provided in the nano-photonic microlens array 130 may be provided in a multilayer structure. For example, the plurality of nanostructures NP may be provided in a first layer and in a second layer provided on the first layer described above. For example, the nano-photonic microlens array 130 may include first layer nanostructures NP1 provided in the first layer and second layer nanostructures NP2 provided in the second layer described above. Although FIG. 19 illustrates that the arrangement of the first layer nanostructures NP1 is the same as the arrangement of the second layer nanostructures NP2, the arrangement of the first layer nanostructure NP1 may be different from the arrangement of the second layer nanostructure NP2. For example, the nanostructures NP may include only the first layer nanostructure NP1, only the second layer nanostructure NP2, or both the first layer nanostructure NP1 and the second layer nanostructure NP2. According to some embodiments of the disclosure, an etch stop layer may be additionally provided between the first layer nanostructure NP1 and the second layer nanostructure NP2.

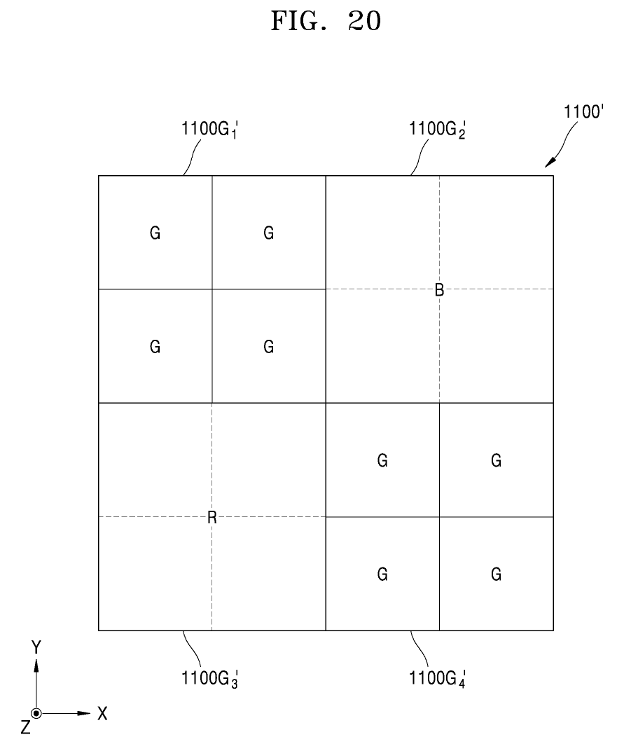

FIG. 20 is a plan view illustrating an arrangement of a pixel array of a pixel array 1100’ according to an embodiment. Differences from FIG. 2 are mainly described with reference to FIG. 20.

The pixel array 1100′ of the image sensor 1000 may include a unit pattern. One unit pattern may include a plurality of unit pixels (e.g., a first unit pixel 1100G₁’, a second unit pixel 1100G₂’, a third unit pixel 1100G₃’, and a fourth unit pixel 1100G₄’). Each of the plurality of unit pixels (e.g., the first unit pixel 1100G₁’, a second unit pixel 1100G₂’, a third unit pixel 1100G₃’, and a fourth unit pixel 1100G₄’) may include at least one pixel provided in a 2×2 arrangement or 4×4 arrangement. For example, each of the first unit pixel 1100G₁’ and the fourth unit pixel 1100G_{4’} may include a plurality of green pixels G arranged in a 2×2 arrangement, the second unit pixel 1100G₂’ may include a blue pixel B, and the third unit pixel 1100G₃’ may include a red pixel R.

Even in this case, the width of the green pixel G provided in a 2×2 arrangement in each of the first unit pixel 1100G₁′ and the fourth unit pixel 1100G₄′ may be less than the width of the blue pixel B provided in the second unit pixel 1100G₂′ or the width of the red pixel R provided in the third unit pixel 1100G₃′. The width of the blue pixel B and/or the width of the red pixel R may be approximately twice as large as the width of the green pixel G.

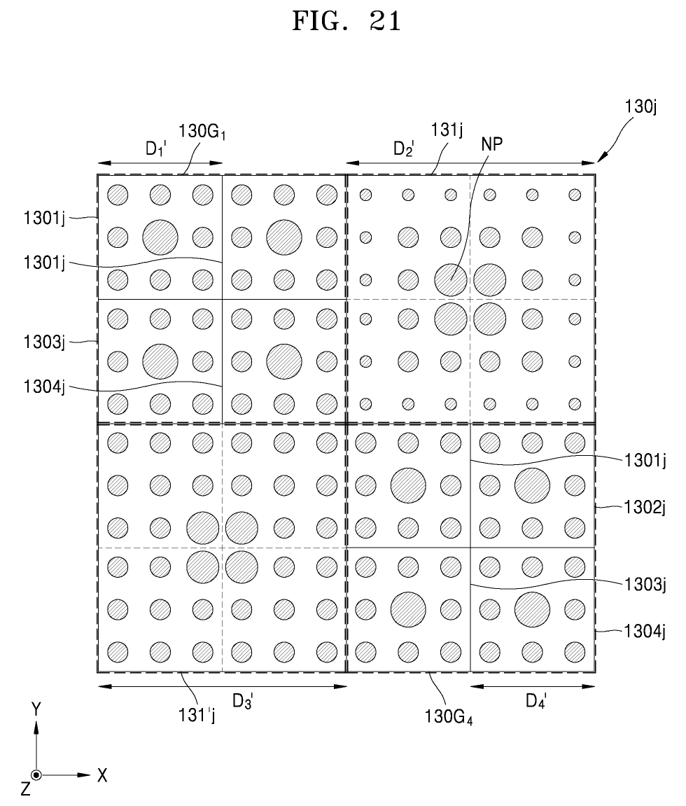

FIG. 21 is a plan view illustrating an arrangement of nanostructures NP included in a nano-photonic microlens array 130j of the pixel array 1100’ of FIG. 20. Differences from FIG. 8 are mainly described with reference to FIG. 21.

Referring to FIG. 21, like FIG. 8, a plurality of nanostructures NP may be provided in each of the pixel corresponding regions (e.g., the first unit pixel corresponding region 130G₁, the second unit pixel corresponding region 130G₂, the third unit pixel corresponding region 130G₃, and the fourth unit pixel corresponding region 130G₄) of the nano-photonic microlens array 130 to form nano-photonic microlenses having different effective diameters for respective colors of light sensed by pixels corresponding to respective regions.

For example, as described above, a plurality of nanostructures NP may be provided to form a plurality of nano-photonic microlenses each having an effective diameter D₁’, in each of the plurality of green pixel corresponding regions 1301j to 1304j provided in each of the first unit pixel corresponding region 130G₁ and the fourth unit pixel corresponding region 130G₄ corresponding to the plurality of green pixels G. In addition, a plurality of nanostructures NP may be provided in the blue pixel corresponding region 131j corresponding to the plurality of blue pixels B to form a plurality of nano-photonic microlenses with an effective diameter D₂’. In addition, a plurality of nanostructures NP may be provided in the red pixel corresponding region 131’j corresponding to the plurality of red pixels R to form a plurality of nano-photonic microlenses with an effective diameter D₃’. Here, effective diameter D₂’ and/or effective diameter D₃’ may be approximately twice as large as the effective diameter D_{1’}.

The image sensor according to an embodiment may constitute a camera module together with module lenses having various performances, and may be used in various electronic apparatuses.

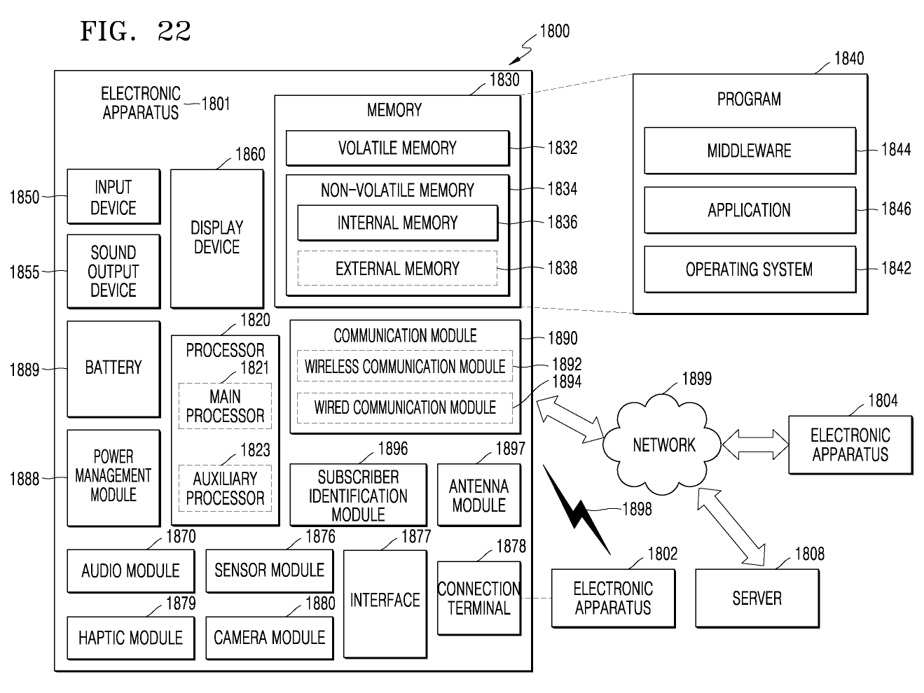

FIG. 22 is a block diagram schematically illustrating an electronic apparatus including an image sensor according to embodiments.

Referring to FIG. 22, in a network environment 1800, the electronic apparatus 1801 may communicate with another electronic apparatus 1802 via a first network 1898 (e.g., a short-range wireless communication network, etc.), and/or may communicate with another electronic apparatus 1804 and/or a server 1808 via a second network 1899 (e.g., a long-range wireless communication network, etc.). The electronic apparatus 1801 may communicate with the electronic apparatus 1804 through the server 1808. The electronic apparatus 1801 may include a processor 1820, a memory 1830, an input device 1850, a sound output device 1855, a display device 1860, an audio module 1870, a sensor module 1876, an interface 1877, a haptic module 1879, a camera module 1880, a power management module 1888, a battery 1889, a communication module 1890, a subscriber identification module 1896, and/or an antenna module 1897. Some (e.g., the display device 1860, and the like) of these components may be omitted from and/or other components may be added to the electronic apparatus 1801. Some of these components may be implemented as one integrated circuit. For example, the sensor module 1876 (e.g., fingerprint sensor, iris sensor, illuminance sensor, etc.) may be implemented by being embedded in the display device 1860 (e.g., display, etc.).

The processor 1820 may execute software (e.g., program 1840 or the like) to control one or a plurality of other components (e.g., hardware, software components, etc.) of the electronic apparatus 1801 connected to the processor 1820, and may perform various data processing or operations. As part of data processing or operation, the processor 1820 may load commands and/or data received from other components (e.g., sensor modules 1876, communication modules 1890, etc.), process commands and/or data stored in volatile memory 1832, and store the result data in nonvolatile memory 1834. The processor 1820 may include a main processor 1821 (e.g., a central processing unit, an application processor, etc.) and an auxiliary processor 1823 (e.g., a graphics processing unit, an image signal processor, a sensor hub processor, a communication processor, etc.) that may be operated independently of or together with the main processor 1821. The auxiliary processor 1823 may use less power than the main processor 1821 and perform a specialized function.

The auxiliary processor 1823 may control the functionality and/or status associated with some of the components of the electronic apparatus 1801 (e.g., the display device 1860, the sensor module 1876, the communication module 1890, etc.), in place of the main processor 1821 while the main processor 1821 is in an inactive state (sleep state), or in conjunction with the main processor 1821 while the main processor 1821 is in an active state (e.g., application execution state). The auxiliary processor 1823 (e.g., image signal processor, communication processor, etc.) may be implemented as part of other functionally related components (e.g., camera module 1880, communication module 1890, etc.).

The memory 1830 may store various data required by components (e.g., processor 1820 and sensor module 1876) of the electronic apparatus 1801. The data may include, for example, input data and/or output data for software (e.g., program 1840 or the like) and related commands. The memory 1830 may include a volatile memory 1832 and/or a nonvolatile memory 1834.

The program 1840 may be stored in the memory 1830 as software, and may include an operating system 1842, middleware 1844, and/or an application 1846.

The input device 1850 may receive commands and/or data to be used in components (e.g., processor 1820, etc.) of the electronic apparatus 1801 from the outside (e.g., user, etc.) of the electronic apparatus 1801. The input device 1850 may include a microphone, a mouse, a keyboard, and/or a digital pen (e.g., a stylus pen).

The sound output device 1855 may output the sound signal to the outside of the electronic apparatus 1801. The sound output device 1855 may include a speaker and/or a receiver. Speakers may be used for general purposes such as multimedia playback or recording playback, and receivers may be used to receive incoming calls. The receiver may be coupled as part of a speaker or may be implemented as an independent separate device.

The display device 1860 may visually provide information to the outside of the electronic apparatus 1801. The display device 1860 may include a display, a hologram device, or a projector and a control circuit for controlling the corresponding device. The display device 1860 may include a touch circuit configured to sense a touch, and/or a sensor circuit (e.g., a pressure sensor, etc.) configured to measure an intensity of a force generated by the touch.

The audio module 1870 may convert sound into an electrical signal or conversely convert the electrical signal into sound. The audio module 1870 may acquire sound through the input device 1850 and/or output sound through the sound output device 1855 and/or a speaker and/or a headphone of another electronic apparatus (e.g., electronic apparatus 1802, etc.) directly or wirelessly connected to the electronic apparatus 1801.

The sensor module 1876 may sense an operating state (e.g., power, temperature, etc.) or an external environmental state (e.g., user state, etc.) of the electronic apparatus 1801 and generate an electrical signal and/or a data value corresponding to the sensed state. The sensor module 1876 may include a gesture sensor, a gyro sensor, an atmospheric pressure sensor, a magnetic sensor, an acceleration sensor, a grip sensor, a proximity sensor, a color sensor, an infrared (IR) sensor, a biometric sensor, a temperature sensor, a humidity sensor, and/or an illumination sensor.

The interface 1877 may support one or more designated protocols that may be used for electronic apparatus 1801 to be directly or wirelessly connected to another electronic apparatus (e.g., electronic apparatus 1802, etc.). The interface 1877 may include a high definition multimedia interface (HDMI), a universal serial bus (USB) interface, an SD card interface, and/or an audio interface.

The connection terminal 1878 may include a connector through which the electronic apparatus 1801 may be physically connected to another electronic apparatus (e.g., electronic apparatus 1802, etc.). The connection terminal 1878 may include an HDMI connector, a USB connector, an SD card connector, and/or an audio connector (e.g., a headphone connector, etc.).

The haptic module 1879 may convert an electrical signal to a mechanical stimulus (e.g., vibration, motion, etc.) or an electrical stimulus that a user can recognize through a tactile or motion sensation. The haptic module 1879 may include a motor, a piezoelectric element, and/or an electrical stimulus.

The camera module 1880 may capture a still image and a moving image. The camera module 1880 may include a lens assembly including one or more lenses, an image sensor 1000 (e.g., a spectral image sensor) of FIG. 1, image signal processors, and/or flashes. The lens assembly included in the camera module 1880 may collect light emitted from a subject to be photographed.

The power management module 1888 may manage power supplied to the electronic apparatus 1801. The power management module 1888 may be implemented as part of a power management integrated circuit (PMIC).

The battery 1889 may supply power to components of the electronic apparatus 1801. The battery 1889 may include a non-rechargeable primary battery, a rechargeable secondary battery, and/or a fuel cell.

The communication module 1890 may establish a direct (e.g., wired) communication channel and/or wireless communication channel between the electronic apparatus 1801 and another electronic apparatus (e.g., the electronic apparatus 1802, the electronic apparatus 1804, the server 1808, etc.), and support communication execution through the established communication channel. The communication module 1890 may include one or more communication processors that operate independently of the processor 1820 (e.g., application processor, etc.) and support direct communication and/or wireless communication. The communication module 1890 may include a wireless communication module 1892 (e.g., a cellular communication module, a short-range wireless communication module, a Global Navigation Satellite System (GNSS), etc.) communication module, and/or a wired communication module 1894 (e.g., a local area network (LAN) communication module, a power line communication module, etc.). A corresponding communication module of these communication modules may communicate with other electronic apparatuses through a first network 1898 (e.g., a short-range communication network such as Bluetooth, WiFi Direct, or infrared data association (IrDA)), or a second network 1899 (e.g., a long-range communication network such as a cellular network, Internet, or computer network (LAN, WAN, etc.)). These various types of communication modules may be integrated into a single component (e.g., a single chip, etc.), or may be implemented as a plurality of separate components (e.g., multiple chips). The wireless communication module 1892 may identify and authenticate the electronic apparatus 1801 in a communication network such as a first network 1898 and/or a second network 1899 using subscriber information (e.g., an international mobile subscriber identifier (IMSI) stored in the subscriber identification module 1896.

The antenna module 1897 may transmit a signal and/or power to the outside (e.g., another electronic apparatus, etc.) or receive the signal and/or power from the outside. The antenna may include a radiator formed of a conductive pattern formed on the substrate (e.g., a printed circuit board (PCB), etc.). The antenna module 1897 may include one or a plurality of antennas. When a plurality of antennas are included, an antenna suitable for a communication scheme used in a communication network such as a first network 1898 and/or a second network 1899 may be selected from among the plurality of antennas by the communication module 1890. A signal and/or power may be transmitted or received between the communication module 1890 and another electronic apparatus through the selected antenna. Other components (e.g., a Radio-Frequency Integrated Circuit (RFIC), etc.) in addition to the antenna may be included as a part of the antenna module 1897.

Some of the components may be connected to each other via communication methods between peripherals (e.g., buses, General Purpose Input and Output (GPIO), Serial Peripheral Interface (SPI), and Mobile Industry Processor Interface (MIPI), etc.) to interchange signals (e.g., commands, data, etc.).

The command or data may be transmitted or received between the electronic apparatus 1801 and the electronic apparatus 1804 (e.g., an external electronic apparatus) through the server 1808 connected to the second network 1899. Other electronic apparatuses 1802 and 1804 may be the same or different types of apparatuses as the electronic apparatus 1801. All or some of the operations executed in the electronic apparatus 1801 may be executed in one or more of the other electronic apparatuses (e.g., the electronic apparatus 1802, the electronic apparatus 1804, and the server 1808). For example, when the electronic apparatus 1801 needs to perform a function or service, it may request one or more other electronic apparatuses to perform part or all of the function or service instead of executing the function or service on its own. One or more other electronic apparatuses receiving the request may execute an additional function or service related to the request and transmit a result of the execution to the electronic apparatus 1801. To this end, cloud computing, distributed computing, and/or client-server computing technology may be used.

FIG. 23 is a block diagram illustrating a camera module of FIG. 22.

Referring to FIG. 23, the camera module 1880 may include a lens assembly 1910, a flash 1920, an image sensor 1000 (see FIG. 1), an image stabilizer 1940, a memory 1950 (e.g., buffer memory, etc.), and/or an image signal processor 1960. The lens assembly 1910 may collect light emitted from a subject to be imaged. The camera module 1880 may include a plurality of lens assemblies 1910, and in this case, the camera module 1880 may be a dual camera, a 360-degree camera, or a spherical camera. Some of the plurality of lens assemblies 1910 may have the same lens properties (e.g., view angle, focal length, autofocus, F Number, optical zoom, etc.), or may have different lens properties. The lens assembly 1910 may include a wide-angle lens or a telephoto lens.

The flash 1920 may emit light used to enhance light emitted or reflected from the subject. The flash 1920 may include one or more light emitting diodes (Red-Green-Blue (RGB) LED, White LED, Infrared LED, Ultraviolet LED, etc.), and/or Xenon Lamps. The image sensor 1000 may be the image sensor described with reference to FIG. 1, and may acquire an image corresponding to a subject by converting light emitted or reflected from the subject and transmitted through the lens assembly 1910 into an electrical signal. The image sensor 1000 may include one or a plurality of sensors selected from image sensors having different attributes, such as an RGB sensor, a black and white (BW) sensor, an infrared (IR) sensor, or an ultraviolet (UV) sensor. Each of the sensors included in the image sensor 1000 may be implemented as a charge coupled device (CCD) sensor and/or a Complementary Metal Oxide Semiconductor (CMOS) sensor.

In response to the movement of the camera module 1880 or the electronic apparatus 1801 including the same, the image stabilizer 1940 may move the one or more lenses or the image sensor 1000 included in the lens assembly 1910 in a specific direction or control an operation characteristic (e.g., adjustment of read-out timing and the like) of the image sensor 1000 to compensate for a negative impact caused by the movement. The image stabilizer 1940 may sense the movement of the camera module 1880 or the electronic apparatus 1801 by using a gyro sensor or an acceleration sensor arranged inside or outside the camera module 1880. The image stabilizer 1940 may be implemented optically.

The memory 1950 may store some or all data of an image acquired through the image sensor 1000 for a next image processing operation. For example, when multiple images are acquired at high speed, the acquired original data (e.g., Bayer-Patterned data, high-resolution data, etc.) may be stored in the memory 1950, and used to allow only low-resolution images to displayed, and then the original data of the selected image (e.g., user selection, or the like) to be transferred to the image signal processor 1960. The memory 1950 may be integrated into the memory 1830 of the electronic apparatus 1801, or may be configured as a separate memory that operates independently.

The image signal processor 1960 may perform image processes on image acquired through the image sensor 1000 (e.g., the spectral image sensor) or image data stored in the memory 1950. The image processes may include depth map generation, three-dimensional modeling, panorama generation, feature point extraction, image synthesis, and/or image compensation (e.g., noise reduction, resolution adjustment, brightness adjustment, blurring interpolation, sharpening, softening, etc.). The image signal processor 1960 may perform control (e.g., exposure time control, read-out timing control, etc.) on components (e.g., image sensor 1000, etc.) included in the camera module 1880. The image processed by the ISP 1960 may be re-stored in the memory 1950 for further processing or may be provided to an external component of the camera module 1880 (e.g., memory 1830, display device 1860, electronic apparatus 1802, electronic apparatus 1804, server 1808, etc.). The ISP 1960 may be integrated into the processor 1820 or may be configured as a separate processor that operates independently of the processor 1820. When the ISP 1960 is configured as a separate processor from the processor 1820, the image processed by the ISP 1960 may be displayed through the display device 1860 after additional image processing by the processor 1820.

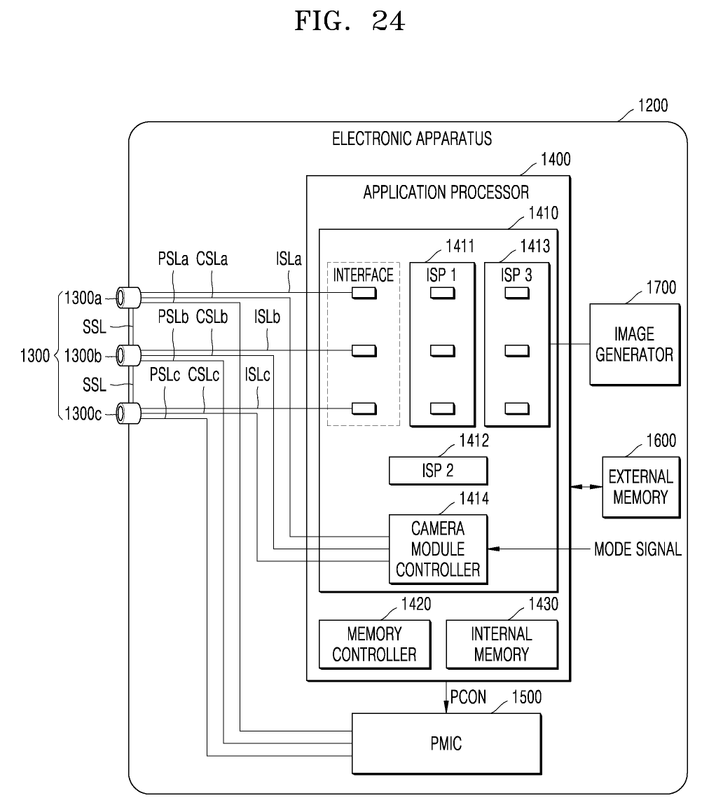

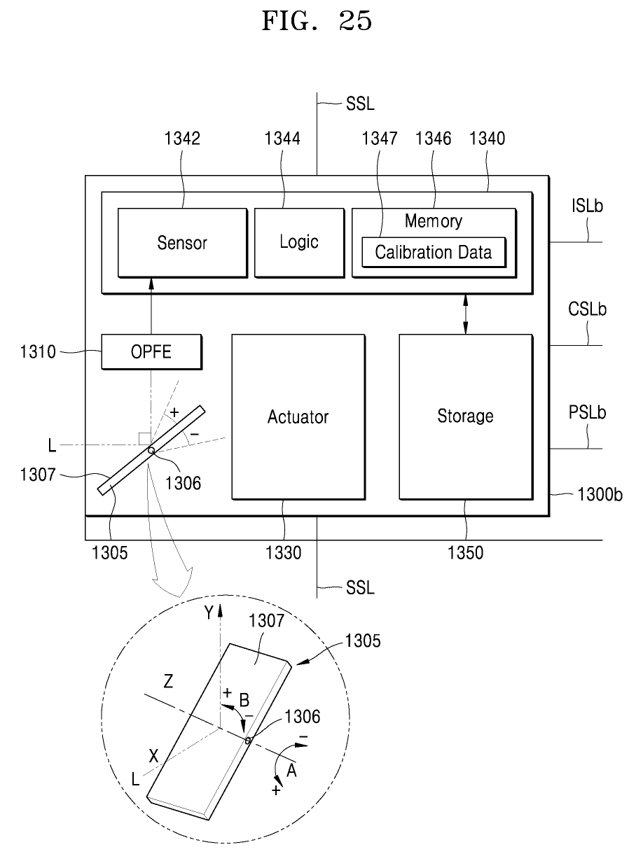

FIG. 24 is a block diagram of an electronic apparatus including a multi-camera module, and FIG. 25 is a detailed block diagram of a camera module of the electronic apparatus illustrated in FIG. 24.

Referring to FIG. 24, an electronic apparatus 1200 may include a camera module group 1300, an application processor 1400, a power management integrated circuit (PMIC) 1500, an external memory 1600, and an image generator 1700.

The camera module group 1300 may include a plurality of camera modules 1300a, 1300b, and 1300c. Although an embodiment in which three camera modules 1300a, 1300b and 1300c are arranged is illustrated in FIG. 14, embodiments of the disclosure are not limited thereto. In some embodiments, the camera module group 1300 may be modified to include only two camera modules. In addition, in some embodiments, camera module group 1300 may be modified to include n camera modules (n is a natural number of 4 or more).

Hereinafter, with reference to FIG. 25, the detailed configuration of the camera module 1300b will be described in more detail, but the following description may be equally applied to other camera modules 1300a and 1300c depending on embodiments.

Referring to FIG. 25, the camera module 1300b may include a prism 1305, an optical path folding element (OPFE) 1310, an actuator 1330, an image sensing device 1340, and a storage 1350.

The prism 1305 may include a reflective surface 1307 of a light reflecting material to transform a path of light L incident from the outside.

In some embodiments, the prism 1305 may change a path of light L incident in a first direction X to a second direction Y perpendicular to the first direction X. In addition, the prism 1305 may change the path of light L incident in the first direction X to a vertical second direction Y by rotating the reflective surface 1370 of the light reflecting material in a direction A around a central axis 1306, or rotating the central axis 1306 in a direction B. In this case, the OPFE 1310 may also move in a third direction Z perpendicular to the first direction X and the second direction Y.

In some embodiments, as illustrated, the maximum rotation angle of the prism 1305 in the direction A may be 15 degrees or less in a plus (+) direction of the direction A and may be greater than 15 degrees in a minus (-) direction of the direction A, but embodiments are not limited thereto.

In some embodiments, the prism 1305 may move around 20 degrees, or between 10 and 20 degrees, or between 15 and 20 degrees, in a positive (+) or negative (-) direction of the direction B, where the moving angle may move at the same angle in a positive (+) or negative (-) direction of the direction B, or to a nearly similar angle in a range of around 1 degree.

In some embodiments, the prism 1380 (and/or the actuator 1330) may move the reflective surface 1370 of the light reflective material in a third direction (e.g., a Z direction) parallel to the extending direction of the central axis 1360.

The OPFE 1310 may include, for example, optical lenses comprising or consisting of m groups of lenses (where m is a natural number). The m groups of lenses may be moved in the second direction Y to change an optical zoom ratio of the camera module 1300b. For example, if the basic optical zoom ratio of the camera module 1300b is Z, and m groups of optical lenses included in the OPFE 1310 are moved, the optical zoom ratio of the camera module 1300b may be changed to an optical zoom ratio of 3Z, 5Z, or 10Z or more.

The actuator 1330 may move the OPFE 1310 or the optical lens (hereinafter, referred to as the optical lens) to a specific position. For example, the actuator 1330 may adjust the position of the optical lens so that an image sensor 1342 is located at the focal length of the optical lens for accurate sensing.

The image sensing device 1340 may include the image sensor 1342, a control logic 1344, and a memory 1346. The image sensor 1342 may sense an image of a subject to be sensed using light L provided through the optical lens. The control logic 1344 may control the overall operation of the camera module 1300b. For example, the control logic 1344 may control the operation of the camera module 1300b according to a control signal provided through a control signal line CSLb.

The memory 1346 may store information for the operation of the camera module 1300b, such as calibration data 1347. The calibration data 1347 may include information to generate image data by using the light L provided from the outside through the camera module 1300b. The calibration data 1347 may include, for example, information on a degree of rotation, information on a focal length, information on an optical axis, and the like described above. When the camera module 1300b is implemented in the form of a multi-state camera whose focal length changes according to the position of the optical lens, the calibration data 1347 may include a focal length value for each position (or state) of the optical lens and information related to autofocus.

The storage 1350 may store image data sensed through the image sensor 1342. The storage 1350 may be arranged outside the image sensing device 1340, and may be implemented in a stacked form with a sensor chip constituting the image sensing device 1340. In some embodiments, the storage 1350 may be implemented as an electrically erasable programmable read-only memory (EEPROM), but embodiments of the disclosure are not limited thereto.

Referring to FIGS. 24 and 25, in some embodiments, each of the plurality of camera modules 1300a, 1300b, and 1300c may include the actuator 1330. Accordingly, each of the plurality of camera modules 1300a, 1300b, and 1300c may include the same or different calibration data 1347 according to the operation of the actuator 1330 included therein.

In some embodiments, one camera module (e.g., 1300b) of the plurality of camera modules 1300a, 1300b, and 1300c may be a camera module in the form of a folded lens including the prism 1380 and the OPFE 1310 described above, and the remaining camera modules (e.g., 1300a and 1300b) may be vertical camera modules without the prism 1380 and the OPFE 1310, but embodiments are not limited thereto.

In some embodiments, one camera module (e.g., 1300c) of the plurality of camera modules 1300a, 1300b, and 1300c may be, for example, a vertical depth camera extracting depth information using an Infrared Ray (IR).

In some embodiments, at least two of the plurality of camera modules 1300a, 1300b, and 1300c (e.g., 1300a and 1300b) may have different field of views or different viewing angles. In this case, for example, the optical lenses of at least two of the plurality of camera modules 1300a, 1300b, and 1300c may be different from each other, but embodiments are not limited thereto.

In addition, in some embodiments, the field of views or the viewing angles of the plurality of camera modules 1300a, 1300b, and 1300c may be different from each other. In this case, optical lenses included in the plurality of camera modules 1300a, 1300b, and 1300c may also be different from each other, but embodiments are not limited thereto.

In some embodiments, each of a plurality of camera modules 1300a, 1300b, and 1300c may be physically separated from each other. That is, rather than using the sensing region of one image sensor 1342 divided by the plurality of camera modules 1300a, 1300b, and 1300c, an independent image sensor (e.g., the image sensor 1342) may be arranged inside each of the plurality of camera modules 1300a, 1300b, and 1300c.

Referring back to FIG. 24, the application processor 1400 may include an image processing device 1410, a memory controller 1420, and an internal memory 1430. The application processor 1400 may be implemented separately from the plurality of camera modules 1300a, 1300b, and 1300c. For example, the application processor 1400 and the plurality of camera modules 1300a, 1300b, and 1300c may be implemented separately from each other by separate semiconductor chips.

The image processing device 1410 may include a plurality of image processors 1411, 1412, and 1413, and a camera module controller 1414.

The image data generated from each of the camera modules 1300a, 1300b, and 1300c may be provided to the image processing device 1410 through image signal lines ISLa, ISLb, and ISLc separated from each other. For example, this image data transmission may be performed using a camera serial interface (CSI) based on a mobile industry processor interface (MIPI), but embodiments of the disclosure are not limited thereto.

The image data transmitted to the image processing device 1410 may be stored in the external memory 1600 before being transmitted to the image processors 1411 and 1412. Image data stored in the external memory 1600 may be provided to the image processor 1411 and/or the image processor 1412. The image processor 1411 may correct the received image data to generate a motion image. The image processor 1412 may correct the received image data to generate a still image. For example, the image processors 1411 and 1412 may perform preprocessing operations such as color correction and gamma correction on image data.

The image processor 1411 may include sub-processors. When the number of sub-processors is the same as the number of camera modules 1300a, 1300b, and 1300c, each of the sub-processors may process image data provided from one camera module. When the number of sub-processors is less than the number of camera modules 1300a, 1300b, and 1300c, at least one of the sub-processors may process image data provided from the plurality of camera modules using a time sharing process. The image data processed by the image processor 1411 and/or the image processor 1412 may be stored in the external memory 1600 before being transmitted to the image processor 1413. Image data stored in the external memory 1600 may be transmitted to the image processor 1413. The image processor 1413 may perform a post-processing operation, such as noise correction and sharpening correction, on the image data.

Image data processed by the image processor 1413 may be provided to the image generator 1700. The image generator 1700 may generate a final image by using image data provided from the image processor 1413 according to image generating information or a mode signal.

Specifically, the image generator 1700 may generate an output image by merging at least some of the image data generated from the camera modules 1300a, 1300b, and 1300c having different field of views or viewing angles according to the image generating information or the mode signal. In addition, the image generator 1700 may generate an output image by selecting any one of image data generated from camera modules 1300a, 1300b, and 1300c with different field of views or viewing angles according to image generating information or mode signal.

In some embodiments, the image generating information may include a zoom signal or a zoom factor. In addition, in some embodiments, the mode signal may be, for example, a signal based on a mode selected by a user.

When the image generating information is a zoom signal (e.g., a zoom factor), and each of the camera modules 1300a, 1300b, and 1300c has different field of views (or different viewing angles), the image generator 1700 may perform different operations according to the type of zoom signal. For example, if the zoom signal is a first signal, the image data output from the camera module 1300a and the image data output from the camera module 1300c may be merged, and then the merged image signal and the image data output from the camera module 1300b which is not used for the image data merging may be used to generate an output image. If the zoom signal is a second signal different from the first signal, the image generator 1700 may generate an output image by selecting any one of the image data output from each of the camera modules 1300a, 1300b, and 1300c without performing such image data merging. However, embodiments of the disclosure are not limited thereto, and a method of processing image data may be modified and implemented.

The camera module controller 1414 may provide a control signal to each of the camera modules 1300a, 1300b, and 1300c. The control signals generated from the camera module controller 1414 may be provided to the corresponding camera modules 1300a, 1300b, and 1300c through control signal lines CSLa, CSLb, and CSLc separated from each other.

In some embodiments, the control signals provided from the camera module controller 1414 to the plurality of camera modules 1300a, 1300b, and 1300c may include mode information according to the mode signal. Based on the mode information, the plurality of camera modules 1300a, 1300b, and 1300c may operate in a first operation mode and a second operation mode in relation to a sensing speed.

In the first operation mode, the plurality of camera modules 1300a, 1300b, and 1300c may generate an image signal at a first speed (e.g., generate an image signal at a first frame rate), encode the generated image signal at a second speed higher than the first speed (e.g., encode an image signal at a second frame rate higher than the first frame rate), and transmit the encoded image signal to the application processor 1400. In this case, the second speed may be 30 times or less of the first speed.

The application processor 1400 may store the received image signal, that is, the encoded image signal, in the internal memory 1430 provided therein or the external memory 1600 outside the application processor 1400, read and decode the encoded image signal from the internal memory 1430 or the external memory 1600, and display image data generated based on the decoded image signal. For example, the image processors 1411 and 1412 of the image processing device 1410 may perform decoding, and the image processor 1413 thereof may also perform image processing on decoded image signals.

In the second operation mode, the plurality of camera modules 1300a, 1300b, and 1300c may generate an image signal at a third speed lower than the first speed (e.g., generate an image signal at a third frame rate lower than the first frame rate) and transmit the image signal to the application processor 1400. The image signal provided to the application processor 1400 may be an unencoded signal. The application processor 1400 may perform image processing on the received image signal or store the image signal in the internal memory 1430 or the external memory 1600.

The PMIC 1500 may supply power, for example, a power supply voltage to each of the plurality of camera modules 1300a, 1300b, and 1300c. For example, under the control of the application processor 1400, the PMIC 1500 may supply first power to the camera module 1300a through a power signal line PSLa, second power to the camera module 1300b through a power signal line PSLb, and third power to the camera module 1300c through a power signal line PSLc.

In response to a power control signal PCON from the application processor 1400, the PMIC 1500 may generate power corresponding to each of the plurality of camera modules 1300a, 1300b, and 1300c, and may also adjust the level of power. The power control signal PCON may include a power adjustment signal for each operation mode of the plurality of camera modules 1300a, 1300b, and 1300c. For example, the operation mode may include a low power mode, and in this case, the power control signal PCON may include information on a camera module operating in a low power mode and information on a set power level. The levels of power provided to each of the plurality of camera modules 1300a, 1300b, and 1300c may be the same or different from each other. Also, the level of power may be dynamically changed.

The image sensor including the nano-photonic microlens array described above and the electronic apparatus including the same have been described with reference to non-limiting example embodiments illustrated in the drawings.

According to an embodiment, since the effective diameter of the nano-photonic microlens formed by the nanostructure is configured differently for each color of light sensed by each pixel, light utilization efficiency may be improved.

It should be understood that example embodiments described herein should be considered in a descriptive sense only and not for purposes of limitation. Descriptions of features or aspects within each example embodiment of the disclosure should typically be considered as available for other similar features or aspects in other embodiments of the disclosure. While one or more example embodiments have been described with reference to the figures, it will be understood by those of ordinary skill in the art that various changes in form and details may be made therein without departing from the spirit and scope of the disclosure.

What is claimed is:

1. An image sensor comprising:
a sensor substrate comprising a plurality of pixels configured to sense incident light; and
a nano-photonic microlens array comprising a plurality of pixel corresponding regions, the plurality of pixel corresponding regions respectively corresponding to the plurality of pixels,
wherein at least two of the plurality of pixel corresponding regions correspond to respective pixels from among the plurality of pixels that are configured to sense light of different wavelengths from each other,
wherein each pixel corresponding region from among the plurality of pixel corresponding regions comprises a nano-photonic microlens, from among nano-photonic microlenses, comprising at least one nanostructure from among a plurality of nanostructures of the nano-photonic microlens array, the nano-photonic microlenses configured to condense the incident light in a respective one of the plurality of pixel corresponding regions, and
wherein effective diameters of the nano-photonic microlenses of the at least two of the plurality of pixel corresponding regions are different from each other.

2. The image sensor of claim 1, wherein
the plurality of pixels comprise a plurality of first pixels configured to sense light, among the incident light, of a first wavelength, and a plurality of second pixels configured to sense light, among the incident light, of a second wavelength different from the first wavelength,
the plurality of pixel corresponding regions comprise a plurality of first pixel corresponding regions respectively corresponding to the plurality of first pixels, and a plurality of second pixel corresponding regions respectively corresponding to the plurality of second pixels,
an effective diameter of the nano-photonic microlenses of the plurality of first pixel corresponding regions is different from an effective diameter of the nano-photonic microlenses of the plurality of second pixel corresponding regions,
the image sensor further comprises a first unit pixel comprising at least two of the plurality of first pixels, and a second unit pixel comprising at least two of the plurality of second pixels, and
a total number of the plurality of first pixels of the first unit pixel is different from a total number of the plurality of second pixels of the second unit pixel.

3. The image sensor of claim 2, wherein a largest diameter nanostructure of each of the plurality of pixel corresponding regions is at a center of each of the plurality of pixel corresponding regions, and
a distance from the largest diameter nanostructure of each second pixel corresponding region from among the plurality of second pixel corresponding regions to a boundary of the second pixel corresponding region is greater than a distance from a center of the largest diameter nanostructure of each first pixel corresponding region of the plurality of first pixel corresponding regions to a boundary of the first pixel corresponding region.

4. The image sensor of claim 2, wherein
the plurality of first pixels are pixels configured to sense green light, and the plurality of second pixels are pixels configured to sense blue light or red light, and
the effective diameter of the nano-photonic microlenses of the plurality of second pixel corresponding regions is two times the effective diameter of the nano-photonic microlenses of the plurality of first pixel corresponding regions.

5. The image sensor of claim 1, wherein
the sensor substrate comprises a first unit pixel and a second unit pixel,
the first unit pixel comprises a plurality of first pixels, from among the plurality of pixels, arranged in a 4×4 arrangement, the plurality of first pixels configured to sense light of a first wavelength,
the second unit pixel comprises a plurality of second pixels, from among the plurality of pixels, arranged in a 2×2 arrangement, the plurality of second pixels configured to sense light of a second wavelength different from the first wavelength,
the plurality of pixel corresponding regions comprise a plurality of first pixel corresponding regions respectively corresponding to the plurality of first pixels, and a plurality of second pixel corresponding regions respectively corresponding to the plurality of second pixels, and
an effective diameter of the nano-photonic microlenses of the plurality of first pixel corresponding regions is different from an effective diameter of the nano-photonic microlenses of the plurality of second pixel corresponding regions.

6. The image sensor of claim 5, wherein an arrangement of the plurality of nanostructures in first pixel corresponding regions, from among the plurality of first pixel corresponding regions, corresponding to first pixels in a central region of the plurality of first pixels is different from an arrangement of the plurality of nanostructures in first pixel corresponding regions, from among the plurality of first pixel corresponding regions, corresponding to first pixels in a peripheral region of the plurality of first pixels.

7. The image sensor of claim 5, wherein an arrangement of the plurality of nanostructures in first pixel corresponding regions, from among the plurality of first pixel corresponding regions, corresponding to first pixels in a peripheral region of the nano-photonic microlens array in a first direction is different from an arrangement of the plurality of nanostructures in first pixel corresponding regions, from among the plurality of first pixel corresponding regions, corresponding to the first pixels in a peripheral region of the nano-photonic microlens array in a second direction different from the first direction.

8. The image sensor of claim 1, wherein
the sensor substrate comprises a first unit pixel and a second unit pixel,
the first unit pixel comprises a plurality of first pixels, from among the plurality of pixels, arranged in a 2×2 arrangement, the plurality of first pixels configured to sense light of a first wavelength,
the second unit pixel comprises a second pixel configured to sense light of a second wavelength different from the first wavelength,
the plurality of pixel corresponding regions comprises a plurality of first pixel corresponding regions respectively corresponding to the plurality of first pixels, and a second pixel corresponding region respectively corresponding to the second pixel, and
an effective diameter of the nano-photonic microlenses of the plurality of first pixel corresponding regions is different from an effective diameter of the nano-photonic microlens of the second pixel corresponding region.

9. The image sensor of claim 1, wherein periods of the at least one nanostructure are different in one of the at least two of the plurality of pixel corresponding regions from another of the at least two of the plurality of pixel corresponding regions.

10. The image sensor of claim 1, wherein the at least one nanostructure of at least one of the plurality of pixel corresponding regions are nanostructures that are at a boundary of the at least one of the plurality of pixel corresponding regions.

11. The image sensor of claim 1, wherein the at least one nanostructure of at least one of the plurality of pixel corresponding regions is a plurality of grid-shaped nanostructures.

12. The image sensor of claim 1, wherein an arrangement of the plurality of nanostructures in a peripheral portion of the nano-photonic microlens array is shifted toward a center direction of the nano-photonic microlens array in comparison to an arrangement of the plurality of nanostructures in a central portion of the nano-photonic microlens array.

13. The image sensor of claim 1, wherein the nano-photonic microlens array comprises a multilayer structure comprising a first layer and a second layer, and
wherein the plurality of nanostructures are in at least one from among the first layer and the second layer.

14. An electronic apparatus comprising:
a lens assembly configured to form an optical image of a subject;
an image sensor configured to convert the optical image formed by the lens assembly into an electrical signal; and
a processor configured to process a signal generated by the image sensor,
wherein the image sensor comprises:
a sensor substrate comprising a plurality of pixels configured to sense incident light; and
a nano-photonic microlens array comprising a plurality of pixel corresponding regions, the plurality of pixel corresponding regions respectively corresponding to the plurality of pixels,
wherein at least two of the plurality of pixel corresponding regions correspond to respective pixels from among the plurality of pixels that are configured to sense light of different wavelengths from each other,
wherein each pixel corresponding region from among the plurality of pixel corresponding regions comprises a nano-photonic microlens, from among nano-photonic microlenses, comprising at least one nanostructure from among a plurality of nanostructures of the nano-photonic microlens array, the nano-photonic microlenses configured to condense the incident light in a respective one the plurality of pixel corresponding regions, and
wherein effective diameters of the nano-photonic microlenses of the at least two of the plurality of pixel corresponding regions are different from each other.

15. The electronic apparatus of claim 14, wherein
the plurality of pixels comprise a plurality of first pixels configured to sense light, among the incident light, of a first wavelength and a plurality of second pixels configured to sense light, among the incident light, of a second wavelength different from the first wavelength,
the plurality of pixel corresponding regions comprise a plurality of first pixel corresponding regions respectively corresponding to the plurality of first pixels, and a plurality of second pixel corresponding regions respectively corresponding to the plurality of second pixels,
an effective diameter of the nano-photonic microlens of the plurality of first pixel corresponding regions is different from an effective diameter of the nano-photonic microlens of the plurality of second pixel corresponding regions,
the image sensor further comprises a first unit pixel comprising at least two of the plurality of first pixels, and a second unit pixel comprising at least two of the plurality of second pixels, and
a total number of the plurality of first pixels included of the first unit pixel is different from a total number of the plurality of second pixels of the second unit pixel.

16. The electronic apparatus of claim 15, wherein
the plurality of first pixels are pixels configured to sense green light, and the plurality of second pixels are pixels configured to sense blue light or red light, and
the effective diameter of the nano-photonic microlenses of the plurality of second pixel corresponding regions is two times the effective diameter of the nano-photonic microlenses of the plurality of first pixel corresponding regions.

17. The electronic apparatus of claim 14, wherein
the sensor substrate comprises a first unit pixel and a second unit pixel,
the first unit pixel comprises a plurality of first pixels, from among the plurality of pixels, arranged in a 4×4 arrangement, the plurality of first pixels configured to sense light of a first wavelength,
the second unit pixel comprises a plurality of second pixels, from among the plurality of pixels, arranged in a 2×2 arrangement, the plurality of second pixels configured to sense light of a second wavelength different from the first wavelength,
the plurality of pixel corresponding regions comprise a plurality of first pixel corresponding regions respectively corresponding to the plurality of first pixels, and a plurality of second pixel corresponding regions respectively corresponding to the plurality of second pixels, and
an effective diameter of the nano-photonic microlenses of the plurality of first pixel corresponding regions is different from an effective diameter of the nano-photonic microlenses of the plurality of second pixel corresponding regions.

18. The electronic apparatus of claim 17, wherein an arrangement of the plurality of nanostructures, from among the plurality of first pixel corresponding regions, corresponding to first pixels in a central region of the plurality of first pixels is different from an arrangement of the plurality of nanostructures in first pixel corresponding regions, from among the plurality of first pixel corresponding regions, corresponding to first pixels in a peripheral region of the plurality of first pixels.

19. The electronic apparatus of claim 17, wherein an arrangement of the plurality of nanostructures in first pixel corresponding regions, from among the plurality of first pixel corresponding regions, corresponding to first pixels in a peripheral region of the nano-photonic microlens array in a first direction is different from an arrangement of the plurality of nanostructures in first pixel corresponding regions, from among the plurality of first pixel corresponding regions, corresponding to the first pixels in a peripheral region of the nano-photonic microlens array in a second direction different from the first direction.

20. The electronic apparatus of claim 14, wherein
the sensor substrate comprises a first unit pixel and a second unit pixel,
the first unit pixel comprises a plurality of first pixels, from among the plurality of pixels, arranged in a 2×2 arrangement, the plurality of first pixels configured to sense light of a first wavelength,
the second unit pixel comprises a second pixel configured to sense light of a second wavelength different from the first wavelength,
the plurality of pixel corresponding regions comprises a plurality of first pixel corresponding regions respectively corresponding to the plurality of first pixels, and a second pixel corresponding region respectively corresponding to the second pixel, and
an effective diameter of the nano-photonic microlenses of the plurality of first pixel corresponding regions is different from an effective diameter of the nano-photonic microlens of the second pixel corresponding region.
